(19) United States
(12) Patent Application Publication
(10) Pub. No.: US 2011/0117477 A1
(43) Pub. Date: May 19, 2011

(54) Photopolymerizable Compositions

(75) Inventors: Pradeep Pareek, Cambridge (GB); Adrian M.D. Horgan, Redhill (GB)

(73) Assignee: SMART HOLOGRAMS LIMITED

(21) Appl. No.: 12/988,140

(22) PCT Filed: Apr. 15, 2009
(86) PCT No.: PCT/GB09/00974

§ 371 Date: Jan. 20, 2011

Related U.S. Application Data
(60) Provisional application No. 61/124,398, filed on Apr. 16, 2008.

(51) Int. Cl. G03F 7/00; G02B 5/32; G03H 1/02; G01B 9/021

(52) U.S. Cl. 430/2; 359/15; 359/3; 356/457

(57) ABSTRACT

Currently known holographic recording media and sensors have a number of disadvantages, for example, silver halide-based recording media is expensive to produce and unsuitable for use in certain sensor applications, and photopolymer-based recording media make it difficult to record multiple holographic images, thus, generally, rendering them unsuitable for use in sensors. Holographic recording media according to an embodiment of the present invention may comprise a polymer matrix and a chemical group that dimerizes by forming a cyclic bridge through photocycloaddition. These holographic recording media are cost-effective, allow recording of multiple holographic images, and enable production of sensors with controlled observable response to an external stimulus.

### RELATED APPLICATION

This application claims the benefit of U.S. Provisional Application No. 61/124,398, filed on Apr. 16, 2008. The entire teachings of the above application are incorporated herein by reference.

### BACKGROUND OF THE INVENTION

Currently known holographic recording media and sensors have a number of disadvantages. For example, in the case of silver halide-based recording media, silver halide particles must be diffused into a polymer matrix, resulting in low cost effectiveness and environmentally unfriendliness. Additionally, silver halide-based recording media is unsuitable for use in certain sensor applications.

Photopolymer holographic recording media are generally prepared by diffusing an ethylenically unsaturated monomer and photoinitiator into a binder (a crosslinked polymer network (e.g., Poly HEMA hydrogel) or hydrophilic polymer (e.g., PVA)). The photoreactive mixture is then exposed to laser light, and this results in the polymerization of monomers within the binder in the exposed areas. This exposure to laser light also produces fringes and records a hologram in the exposed areas. However, the unexposed areas of the photopolymer holographic recording media (binder with monomer) are not stable. The monomers in the unexposed areas tend to polymerize randomly, which can result in poor diffraction efficiencies and undesired wavelength changes. In addition, phase separation of the monomer and binder in the unexposed areas further complicates the holographic properties of the photopolymer holographic recording media: In addition to these undesirable properties of photopolymer-based recording media, it is difficult to record multiple holographic images in such media. Thus, photopolymer-based recording media are generally not suitable for use in sensors.

### SUMMARY OF THE INVENTION

An embodiment of the present invention relates to a holographic sensor comprising (a) a holographic recording media comprising a polymer matrix and (b) at least one holographic image recorded in said holographic recording media as diffraction fringes, wherein the diffraction fringes comprise a dimeric structure that includes a cyclic bridge. The holographic recording media responds to an external stimulus by providing at least one output signal.

An embodiment of the present invention also relates to a holographic recording media. The holographic recording media comprises (a) a polymer matrix and (b) a plurality of dimerisable chemical groups, wherein (i) the dimerisable chemical groups dimerize by forming a cyclic bridge through photocycloaddition and (ii) the dimerisable chemical groups are distributed throughout the polymer matrix in a density sufficient to allow (1) recording of a hologram by dimerization of part of the dimerisable chemical groups and (2) detection of a change of the optical properties of the hologram upon response of the polymer matrix to the presence of an external stimulus.

An embodiment of the present invention also relates to a method of detecting the presence of an external stimulus. The method comprises changing the relative spatial positions of dimeric structures, relative to each other and to dimerisable chemical groups, in response to the external stimulus to provide an observable holographic image or an observable change of a holographic image, the presence or change of the observable holographic image being indicative of the presence of the external stimulus.

An embodiment of the present invention also relates to a method for recording a holographic image. The method comprises controlling (1) the fraction of dimerization of dimerisable chemical groups that form dimeric structures by photocycloaddition and (2) retention of spatial positions of the dimeric structures, relative to each other and to dimerisable chemical groups that did not dimerize, to record the holographic image and enable a controlled observable response of the recorded holographic image, in a later presence of an external stimulus. A controlled observable response typically is an output signal. For example, the controlled observable response may be a change of the replay wavelength of the recorded holographic image in a controlled manner, for example, towards longer wavelengths in the presence of an external stimulus.

An embodiment of the present invention also relates to a method for recording a holographic image, the method comprising: (a) dimerizing dimerisable chemical groups through photocycloaddition to form dimeric structures in response to photons representing the holographic image, (b) retaining spatial positions of the dimeric structures, relative to each other and to dimerisable chemical groups that did not dimerize, to retain a recorded holographic image, in a manner enabling a controlled observable response of the recorded holographic image as a function of the dimerizing and retaining in a later presence of an external stimulus.

An embodiment of the present invention also relates to a method for recording a holographic image, the method comprising: (a) retaining spatial positions of dimerisable chemical groups and dimeric structures, wherein the dimerisable chemical groups form dimeric structures through photocycloaddition; and (b) dimerizing the dimerisable chemical groups through photocycloaddition to form dimeric structures in response to photons representing the holographic image, to retain a recorded holographic image, while (c) enabling a controlled observable response of the recorded holographic image, as a function of the dimerizing and retaining in a later presence of an external stimulus.

An embodiment of the present invention also relates to a method of detecting the presence of an external stimulus. The method comprises (1) providing a holographic sensor and (2) detecting the presence of at least one output signal provided by the holographic sensor to thereby detect the presence of the external stimulus. The holographic sensor includes (a) a holographic recording media having a polymer matrix and (b) at least one holographic image recorded in said holographic recording media as diffraction fringes, wherein the diffraction fringes comprise a dimeric structure that includes a cyclic bridge. The holographic recording media responds to an external stimulus by providing at least one output signal.

An embodiment of the present invention also relates to a method of manufacturing a holographic sensor. The method comprises recording at least one holographic image as diffraction fringes in a holographic recording media, the holographic recording media including (i) a polymer matrix and (ii) a plurality of dimerisable chemical groups that dimerize by forming a cyclic bridge through photocycloaddition; wherein the diffraction fringes comprise a plurality of dimeric structures that include a cyclic bridge and wherein the holographic recording media responds to an external stimulus by providing at least one output signal.

Embodiments of the present invention also relate to a holographic sensor prepared by any of the above described methods.

An embodiment of the present invention also relates to a holographic recording media, comprising a polymer matrix, and a chemical group that dimerizes by forming a cyclic bridge through photocycloaddition. A physical or a chemical property of the holographic recording media varies in response to an external stimulus. The holographic recording media provides advantages over photopolymer-bases media which rely on photo-polymerization to induce refractive index modulation. In contrast, refractive index modulation in the holographic recording media of this embodiment of the invention is induced by photocycloaddition.

An embodiment of the present invention also relates to a holographic sensor, comprising a holographic recording media and at least one image recorded in said holographic recording media as diffraction fringes. The diffreaction fringes comprise a dimeric chemical group that includes a cyclic bridge. The holographic recording media responds to an external stimulus by generating at least one readout signal.

An embodiment of the present invention also relates to a method of detecting an external stimulus, comprising applying an external stimulus to a holographic sensor that comprises a holographic recording media and at least one image recorded in said holographic recording media as diffraction fringes, wherein the diffraction fringes comprise a dimeric chemical group that includes a cyclic bridge, and the holographic recording media responds to an external stimulus by generating at least one readout signal; and detecting at least one readout signal.

An embodiment of the present invention also relates to a method of manufacturing a holographic sensor, comprising (a) manufacturing or providing a holographic recording media that comprises (i) a polymer matrix, and (ii) a chemical group that dimerizes by forming a cyclic bridge through photocycloaddition; and (b) recording at least one image as diffraction fringes in said holographic recording media. The diffraction fringes comprise a dimeric chemical group that includes a cyclic bridge. The holographic recording media responds to an external stimulus by generating at least one readout signal.

The holographic recording media of embodiments of the present invention has a number of advantages. The manufacturing process is simplified, relative to silver halide-based and other types holographic recording media, because the step of diffusing silver particles into the polymer matrix can be eliminated. By selecting the materials of the polymer matrix and the dimerisable chemical group, the embodiments of the inventive recording media and the sensors comprising same can be optimized for use in various areas such as medical diagnostics and monitoring (e.g., immunodiagnostics, glucose monitoring) and security applications. Additionally, the photocycloaddition reaction can be used not only to create the interference pattern fringes, but also to create a cross-linked polymer matrix, e.g., a hydrogel. This further simplifies the manufacturing methods by allowing production of a holographic sensor in a one-step process. Additionally, the holograms recorded using the holographic recording media of embodiments of the present invention possess superior diffraction efficiencies.

### BRIEF DESCRIPTION OF THE DRAWINGS

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

FIG. 1 is a graph showing measurements of the change in replay wavelength of a holographic sensor, comprising holographic fringes recorded in a holographic recording media according to an embodiment of the invention, when exposed to liquids with different pHs. The replay wavelength of the recorded hologram changed by 149 nm in response to a pH change of 1.5 units (from pH 6 to pH 7.5).

FIG. 2 shows methods for preparing and recording fringes in holographic recording media according to some embodiments of the invention.

FIG. 3 is a graph showing measurements of the effect of various glucose concentrations on the replay wavelength of a glucose responsive photopolymer hologram.

FIG. 4 is a diagram that shows a method for recording fringes in a holographic recording media according to an embodiment of the invention while curing the holographic recording media at the same time.

FIG. 5 is a schematic representation comparing a method for preparing a photopolymer hologram that does not include post-curing of residual dimerisable groups (left) with a method according to an embodiment of the invention for preparing a photopolymer hologram that includes post-curing of residual dimerisable groups (right).

FIG. 6 is a diagram illustrating an example manufacturing process that may be employed to manufacture holographic recording media according to an embodiment of the invention.

FIG. 7 is another diagram illustrating an example manufacturing process that may be employed to manufacture holographic recording media according to an embodiment of the invention.

FIG. 8 is a schematic representation of the recording of a holographic image in a holographic recording media using a laser to prepare a holographic sensor according to an embodiment of the present invention, showing the chemical changes due to dimerization in the polymer matrix according to an embodiment of the present invention, and showing the application of the holographic sensor in detecting an external stimulus by providing a controlled observable response.

### DETAILED DESCRIPTION OF THE INVENTION

A description of example embodiments of the invention follows.

The term “alkyl”, as used herein, unless otherwise indicated, includes straight or branched saturated monovalent hydrocarbons, typically C1-C20, preferably C10 or C1-C6. Examples of alkyl groups include, but are not limited to, methyl, ethyl, propyl, isopropyl, and t-butyl. Suitable substituents for a substituted alkyl include —OH, —SH, halogen, cyano, nitro, amino, —COOH, —COX (where X=Cl, Br, I), a C1-C3 alkyl, C1-C3 haloalkyl, C1-C3 alkoxy, C1-C3 haloalkoxy or C1-C3 alkyl sulfanyl, or —(CH₂)ₚ—(CH₂)_{q}—C(O)OH, where p and q are independently an integer from 1 to 10.

The term “cycloalkyl”, as used herein, is a non-aromatic saturated carbocyclic moieties. Examples of cycloalkyl include, but are not limited to, cyclopropyl, cyclobutyl, cyclopentyl, cyclohexyl, and cycloheptyl. Suitable substituents for a cycloalkyl are defined above for an alkyl.

The term “hydrocarbon ring”, as used herein, is a carbocyclic ring systems typically having four to eight members, preferably five to six, in which one or more bonds are optionally unsaturated.

As used herein, “dialkyl” or “alkylene” is a moiety having a structural formula —(CRₖRₗ)ₘ—, wherein Rₖ and Rₗ may be each independently a hydrogen or any of the optionally substituted alkyls described above, and m is an integer greater than or equal to one.

The terms “alkoxy”, as used herein, means an “alkyl-O—” group, wherein alkyl, is defined above.

The term “aryl”, as used herein, refers to a carbocyclic aromatic group.

Examples of aryl groups include, but are not limited to phenyl and naphthyl.

The term “aryloxy”, as used herein, means an “aryl-O—” group, wherein aryl is defined above.

The term “non-aromatic heterocycle” refers to non-aromatic carbocyclic ring systems typically having four to eight members, preferably five to six, in which one or more ring carbons, preferably one to four, are each replaced by a heteroatom such as N, O, or S, Non aromatic heterocycles can be optionally unsaturated. Examples of non-aromatic heterocyclic rings include 3-tetrahydrofuranyl, 2-tetrahydropyranyl, 3-tetrahydropyranyl, 4-tetrahydropyranyl, [1,3]-dioxalanyl, [1,3]-dithiolanyl, [1,3]-dioxanyl, 2-tetrahydrothiophenyl, 3-tetrahydrothiophenyl, 2-morpholinyl, 3-morpholinyl, 4-morpholinyl, 2-thiomorpholinyl, 3-thiomorpholinyl, 4-thiomorpholinyl, 1-pyrrolidinyl, 2-pyrrolidinyl, 3-pyrorolidinyl, 1-piperazinyl, 2-piperazinyl, 1-piperidinyl, 2-piperidinyl, 3-piperidinyl, 4-piperidinyl, 4-thiazolidinyl, diazolonyl, N-substituted diazolonyl, and 1-pthalimidinyl.

As used herein, an amino group may be a primary (—NH₂), secondary (—NHRₓ), or tertiary (—NRₓR_{y}), wherein Rₓ and R_{y} may be any of the optionally substituted alkyls described above.

The non-aromatic heterocyclic groups may be C-attached or N-attached (where such is possible). For instance, a group derived from pyrrole may be pyrrol-1-yl (N-attached) or pyrrol-3-yl (C-attached).

As used herein “PEG” refers to poly(ethylene glycol), preferably with an average molecular weight of ≦12000 Da.

As used herein “NHS” and “sulfo-NHS” refer to N-hydroxysuccinimide and sulfo-N-hydroxysuccinimide, respectively.

Suitable substituents for an aryl, a heteroaryl, or a non-aromatic heterocyclic group are those that do not substantially interfere with the activity of the disclosed compounds. One or more substituents can be present, which can be identical or different. Examples of suitable substituents for a substitutable carbon atom in aryl, heteroaryl or a non-aromatic heterocyclic group include —OH, halogen (—F, —Cl, —Br, and —I), —R′, haloalkyl, —OR′, —CH₂R′, —CH₂OR′, —CH₂CH₂OR′, —CH₂OC(O)R′, —O—COR′, —COR′, —SR′, —SCH₂R′, —CH₂SR′, —SOR′, —SO₂R′, —CN, —NO₂, —COOH, —SO₃H, —NH₂, —NHR′, —N(R′)₂, —COOR′, —CH₂COOR′, —CH₂CH₂COOR′, —CHO, —CONH₂, —CONHR′, —CON(R′)₂, —NHCOR′, —NR′COR′, —NHCONH₂, —NHCONR′H, —NHCON(R′)₂, —NR′CONH₂, —NR′CONR′H, —NR′CON(R′)₂, —C(═NH)—NH₂, —C(═NH)—NHR′, —C(═NH)—N(R′)₂, —C(═NR′)—NH₂, —C(═NR′)—NHR′, —C(═NR′)—N(R′)₂, —NH—C(═NH)—NH₂, —NH—C(═NH)—NHR′, —NH—C(═NH)—N(R′)₂, —NH—C(═NR′)—NH₂, —NH—C(═NR′)—NHR′, —NH—C(═NR′)—N(R′)₂, —NR′H—C(═NH)—NH₂, —NR′—C(═NH)—NHR′, —NR′—C(═NH)—N(R′)₂, —NR′—C(═NR′)—NH₂, —NR′—C(NR′)—NHR′, —NR′—C(═NR′)—N(R′)₂, —SO₂NH₂, —SO₂NHR′, —SO₂NR′₂, —SH, —SOₖR′ (k is 0, 1 or 2) and —NH—C(═NH)—NH₂. Each R′ is independently an alkyl group. Oxo (C═O) and thio (C═S) are also suitable substituents for a non-aromatic heterocycle.

Suitable substituents on the nitrogen of a non-aromatic heterocyclic group or a heteroaryl group include —R″, —N(R″)₂, —C(O)R″, —CO₂R″, —C(O)C(O)R″, —C(O)CH₂C(O)R″, —SO₂R″, —SO₂N(R″)₂, —C(═S)N(R″)₂, —C(═NH)—N(R″)₂, and —NR″ SO₂R″. R″ is hydrogen, an alkyl or alkoxy group.

Further examples of suitable substituents for a substitutable carbon atom in an aryl, a heteroaryl, or a non-aromatic heterocyclic group include but are not limited to —OH, halogen (—F, —Cl, —Br, and —I), —R, —OR, —CH₂R, —CH₂OR, and —CH₂CH₂OR. Each R is independently an alkyl group.

The word “cycloaddition” is a term of art that refers to a pericyclic chemical reaction, in which at least two π bonds are lost and at least two a bonds are gained, the resulting reaction being a cyclization reaction. (See, e.g., “March's Advanced Organic Chemistry”, M. B. Smith and J. March, Fifth Edition, pp. 1062-1093.)

As used herein, a “cyclic bridge” refers to a “hydrocarbon ring” or a “non-aromatic heterocycle”, as defined above, that is formed by a cycloaddition reaction. For example, two unsaturated rings can be dimerized through cycloaddition reaction that produces a cyclobutane bridge, as shown in Method 1. A photosensitizer can also be used to trigger a photo cycloaddition reactions. In presence of a suitable photo sensitizer, the photo cycloaddition reaction can be tuned to occur at different wavelengths. For example, the UV absorption of the dimethylmaleimide lies in the region of 270-300 nm. Thus, the cycloaddition of dimethylmaleimide groups requires a light source with an emission maximum in the deep UV. However, in presence of a suitable thioxanthone, the cycloaddition reaction can be sensitized towards the near UV (360-430 nm)

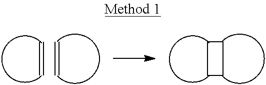

As used herein, a “chemical group that dimerizes through a cyclic bridge” refers an unsaturated ring that is a optionally part of a larger compound, wherein two such chemical groups can react in a cycloadditon reaction to dimerize through a cyclic bridge. Examples of chemical groups that dimerize through a cyclic bridge include cinnamoyl, chalcone, anthracene, coumarin, stilbazolium, maleimide, and derivatives thereof. A four membered ring structure can be formed by 2+2 cycloaddition and 8 membered ring structure can be formed by 4+4 cycloaddition. Examples of chemical groups undergoing such reactions are shown above. Chemical groups can be covalently attached to a polymeric chain (pendant group) or can be admixed to the polymeric matrix in a form of an chemical compound that provides a chemical group that dimerize through a cyclic bridge. When two chemical groups that dimerize through a cyclic bridge dimerize, they form a “dimer” or a “dimeric compound”.

“Actinic radiation” is a term of art that refers to electromagnetic energy that has the capacity to produce photochemical activity. Examples of actinic radiation include UV radiation, visible light, IR radiation, α-, β-, or γ-radiation, and X-rays.

An embodiment of the invention relates to a holographic recording media that comprises a chemical group that dimerizes through a cyclic bridge and a polymer matrix, and to a sensor comprising the holographic recording media with a hologram recorded therein. The chemical group the dimerizes through a cyclic bridge can be a component of the polymer matrix (e.g., a pendant group), or can be a separate compound or a component of a separate compound. As described herein, holograms can be recorded in the holographic recording media by causing the chemical group that dimerizes through a cyclic bridge to dimerize, thereby forming fringes. A physical or a chemical property of the holographic recording media varies in response to an external stimulus. Thus, the holographic recording media can be used to prepare holographic sensors for detecting or quantifying an external stimulus. For example, when a hologram is recorded in the recording media, a change in physical or chemical property of the recording media, can result in a shift in the hologram replay wavelength. In particular examples, a hologram that replays in the visible spectrum in the absence of external stimulus may replay in the UV or IR spectrum in the presence of stimulus, or a hologram that replays in one color in the absence of stimulus may replay in a different color in the presence of stimulus.

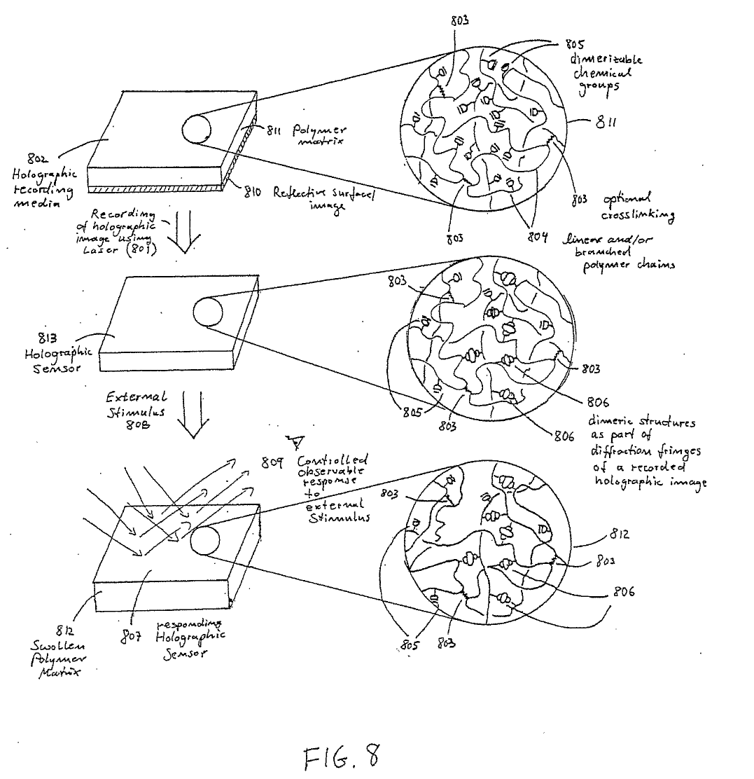

FIG. 8 is a schematic representation showing a holographic recording media (Item 802) according to an embodiment of the present invention, the recording (Item 801) of a holographic image in the holographic recording media according to an embodiment of the present invention (Item 802) to form a holographic sensor according to an embodiment of the present invention (Item 813), and the detection of an external stimulus (Item 808) using the holographic sensor. The holographic recording media includes a polymer matrix (Item 811), and is positioned on a reflective surface/image (Item 810). Prior to recording, the polymer matrix (Item 811) according to an embodiment of the present invention includes linear and/or branched polymer chains (Item 804) that include optional crosslinking (Item 803) and dimerizable chemical groups (Item 805). During recording, dimerizable chemical groups dimerize via photocycloaddition to form dimeric structures (Item 806). These dimeric structures are part of diffraction fringes of the recorded holographic image of the holographic sensor. According to an embodiment of the present invention, the polymer matrix of the holographic sensor swells in the presence/in contact with an external stimulus (Item 808) to a swollen polymer matrix (Item 812) and the responding holographic sensor (Item 807) provides a controlled observable response (Item 809) to the external stimulus (808), for example, an output signal such as a change of the replay wavelength of the recorded holographic image.

### Holographic Recording Media of the Present Invention

In one embodiment, the present invention is a holographic recording media that comprises a chemical group that dimerizes through a cyclic bridge and a polymer matrix. A physical or a chemical property of the holographic recording media varies in response to an external stimulus.

The holographic recording media can be prepared so that a physical or chemical property of the media varies in response to a desired external stimulus. For example, if desired, the holographic recording media can also include means to detect a desired external stimulus, such as an analyte, so that interaction with an analyte results in a variation of a property of the medium. Generally such means have binding affinity for the analyte, and include, for example, ligands (e.g., boronic acids), chelators (e.g., cyclam), enzymes, antibodies, receptors and ligands cognate to an analyte to be detected. One or more such means can be included in the media using any suitable method.

In some embodiments, the external stimulus is one or more of humidity, water, gases, vapor, organic or inorganic solvent, chemicals, metal ions, solutions or dispersions of chemicals, pressure, temperature, acidity, electromagnetic waves, magnetic field, electrical field, ionizing radiation, a protic material, an aprotic or apolar material, a fluid, or a fluid comprising an analyte. Analytes can be but are not limited to a protein, a peptide, a polypeptide, an amino acid, a nucleic acid, an oligonucleotide, a therapeutic agent, a metabolite of a therapeutic agent, RNA, DNA, an antibody, an organism, a virus, a bacterium, a carbohydrate, a monosaccharide, a disaccharide, a polysaccharide, a lipoprotein, a fatty acid, a glycoprotein, a proteoglycan, or a lipopolysaccharide. Typically, analytes can be proteins, nucleic acids, monosaccharides, disaccharides, polysaccharides, and microorganisms. More typically, analytes can be monosaccharides or disaccharides. More particular examples of external stimuli include blood analytes such as glucose, lactose, lactate, potassium, or CO₂, air temperature, relative humidity, vapors of a poisonous or flammable gas, organophosphates, UV radiation, X-rays, γ-radiation, viruses, anthrax spores, antibody-producing agents such as liposaccharides, or changes of the acidity (pH) of the liquid environment.

“Aprotic materials” as referred to herein, refers to aprotic solvents such as, for example, perfluorohexane, α,α,α-trifluorotoluene, pentane, hexane, cyclohexane, methylcyclohexane, decalin, dioxane, carbon tetrachloride, freon-11, benzene, toluene, triethyl amine, carbon disulfide, diisopropyl ether, diethyl ether (ether), t-butyl methyl ether (MTBE), chloroform, ethyl acetate, 1,2-dimethoxyethane (glyme), 2-methoxyethyl ether (diglyme), tetrahydrofuran (THF), methylene chloride, pyridine, 2-butanone (MEK), acetone, hexamethylphosphoramide, N-methylpyrrolidinone, nitromethane, dimethylformamide, acetonitrile, sulfolane, dimethyl sulfoxide and propylene carbonate, and apolar and weakly polar compounds such as, for example, alkanes and ketones.

“Protic materials” as referred to herein, refers to protic solvents such as, for example, propionic acid, diethyl amine. butyl amine, propyl amine, acetic acid, trifluoroacetic acid (TFA), phenol, isopropyl alcohol, ammonia (anhyd.), ethanol, (ethyl alcohol), 2,2,2-trifluoroethanol, methyl alcohol, ethylene glycol, glycerol, formic acid, water and formamide, and polar compounds.

Generally, the physical or chemical property that varies in response to an external stimulus is at least one of volume of the media, size of the media, density of the media, specific mass of the media, refractive index of the media, and the refractive index of the dimerized chemical group. Other examples of the physical or chemical properties of the recording media that can vary in response to an external stimulus are shape, hardness, hydrophobicity, integrity, polarizability, and charge distribution.

Compounds that contain a chemical group that dimerizes through a cyclic bridge employed in the holographic recording media to produce fringes may dimerize by forming a cyclic bridge through a photocycloaddition reaction. Examples of the cyclic bridge include a cyclobutyl, cyclopentyl, cyclohexyl, cycloheptyl, cyclooctyl, and the like. An example cyclic bridge is cyclobutyl.

The reactivity of the double bond of the dimerisable chemical group, such as, the compound represented by structural formula (I) below, that takes part in forming the cyclic bridge can be varied by incorporating electron withdrawing or donating groups or optionally other groups which influence “molecular stability” as substituents on the double bond, for example, as groups R1 and R2 as shown in the compound represented by structural formula (I). It is believed that an improved reactivity corresponds to a reduction in the required photon energy, thereby bringing the recording wavelength into the visible spectrum range. Further, groups which assist stabilization of the cyclic bridge, such as, cyclobutane ring after hologram recording (also herein referred to as “hologram writing”), can be used to vary the recording wavelength. Similarly these can be used to modify the dimerisation reaction and ring stability as above. There are many such possibilities.

The chemical group that dimerizes through a cyclic bridge employed in the holographic recording media according to an embodiment of the present invention can dimerize reversibly or substantially irreversibly. In some embodiments, the chemical groups that dimerize through a cyclic bridge employed in the holographic recording media dimerize substantially irreversibly. Irreversible dimer formation can be readily determined using any suitable method, such as by exposing a dimeric compound to light (e.g., laser) having a wavelength of form about 250 nm to about 320 nm (e.g., 250 nm, 260 nm, 270 nm, 280 nm, 290 nm, 300 nm, 310 nm, 320 nm), preferably 290 nm in some applications, and determining if the dimeric compound remains or is converted to monomers. For example, the maleimide group dimerizes substantially irreversibly through photocycloaddition, and is stable when exposed to light of 290 nm, while anthracene dimerizes reversibly.

Examples of dimerisable chemical groups suitable for use in some embodiments of the present invention include cinnamoyl, chalcone, anthracene, coumarin, stilbazolium, maleimide, and derivatives thereof. One or more compounds that contain these groups or their derivatives can be used. In certain embodiments, the dimerisable chemical groups are covalently attached to polymer matrix of the holographic recording media. For example, the dimerisable chemical group can be a pendant group that is a component of the polymer matrix. This type of holographic recording media can be prepared by using any suitable method, such as by preparing a polymer that comprises a monomer that contains the dimerisable chemical group as described herein, or by reacting a compound that contains a dimerisable chemical group and a functional group with a polymer matrix that contains a complementary functional group to form a chemical bond, preferably a covalent bond. Any suitable functional group and complementary functional group can be used. Many suitable functional groups and complementary functional groups are well-known in the art, for examples, electrophilic groups such as haloketones or halomethyl ketones can react with nucleophilic groups such as —OH. Other functional groups can be amines (primary, secondary and tertiary), —COOH, —COX (where X═F, Cl, Br, I,), disulphides and esters of N-hydroxy succinimides.

In other embodiments, the dimerisable chemical group is not covalently attached to the polymer matrix. In one example, the dimerisable chemical group is part of a compound that is present (e.g., in solution) within the polymer matrix. The holographic recording media of this example, can be prepared using any suitable method, such as by diffusing a compounds that comprises a dimerisable chemical group into a suitable polymer matrix and then drying the matrix to the desired degree, if desired.

The polymer matrix can be any suitable polymer matrix, and, when the polymer matrix is hydrophilic, typically is prepared by polymerizing one or more monomers to form a hydrogel. Monomers that can be polymerized to form a hydrogel include, hydrophilic monomers (anionic, cationic, non ionic monomers and zwitterionic monomers), and amphiphilic monomers. Additional monomers, such as hydrophobic monomers can be included to form copolymers, if desired. If desired, the polymer matrix can be or comprise a biopolymer or biocompatible polymer, such as polymers that comprise 2-Methacryloyloxyethyl phosphorylcholine monomer (MPC).

The polymer matrix can be or comprise a polymer prepared by polymerizing one or more hydrophobic monomers. Examples of suitable hydrophobic monomers and properties, crosslinking and synthesis of various hydrophobic polymers are described in George Odian's book, Principles of Polymerization, third edition, Wiley-Interscience (in particular, on pages 121 to 141, 155 to 158, 303 to 314 and 518 to 522), the entire teachings of which are herein incorporated by reference.

Hydrophobic polymers suitable for the present invention include, for example, poly(stryrene), poly(urethane), polycarbonates, polyamides, poly(fluorocarbons), polyolefins, polyesters, polyacrylates and alkylacrylates, polysiloxanes, polyacetals and their copolymers.

While substantially not swellable in aqueous solutions, hydrophobic polymers can non-specifically absorb aprotic materials, for example, molecular vapours of alkanes, ketones, and chlorine-containing molecules. Therefore, when hydrophobic polymers are used to provide a polymer matrix of holographic sensors according to an embodiment of the present invention, the holographic sensor provides an output signal, for example, a change in the replay wavelength of a recorded hologram upon exposure to aprotic materials, such as molecular gases of aprotic solvents or apolar compounds due to the swelling of the hydrophobic polymer matrix.

Examples of suitable hydrophilic monomers include 2-hydroxyethylmethacrylate (HEMA), 2-hydroxypropylmethacrylate (HPMA), N,N-dimethylacrylamide (DMAA), poly(ethylene glycol) mono-methacrylate (PEGMA), poly(vinyl alcohol), vinyl acetate, acrylic acid (AA), acrylamide, methacrylic acid (MAA), N,N-methylenebisacrylamide (BIS), ethyleneglycol dimethacrylate (EDMA), 2-acrylamido-2-methylpropane sulfonic acid (AMPS), sodium salt of methacrylic acid, 2-(dimethylaminoethyl)methacrylate (DMAEMA), Styrene 4-sulfonic acid, 2-(N,N Dimethyl-N-(2-methacryloxyethyl)ammonium)ethanoic acid, and the like. Suitable hydrophilic polymers include polymers and copolymers of these monomers. Specific examples of hydrophilic polymers include, poly(ethylene glycol) mono-methacrylate (PEGMA), poly(vinyl alcohol), poly(ethylene glycol), poly(glycidols), poly(ethylene oxide), poly(acrylamide), poly(vinyl pyrrolidone), poly(methyl vinyl ether) and the like.

The polymer matrix can be or comprise a stimuli responsive polymer, such as a polymer that is responsive to pH, temperature, moisture (e.g., water in liquid, vapor or gas form) or a biochemical stimulus. Examples of suitable stimuli responsive polymers include poly(N-isopropylacrylamide) (p(NIPAAm)), poly(N-isopropylmethacrylamide), poly(N-ethyl-N-methylacrylamide), poly(N,N-diethylacrylamide), poly(N,N-dimethylaminoethylmethacrylate), poly(vinylcaprolactam), poly(vinylisobutyroamide), poly(methylvinylether), poly(ethyleneoxide), poly(2-ethyloxazoline), hydroxypropylcellulose and the like. Examples of polymers that are pH responsive include poly(2-vinylpyridine), poly(4-vinylpyridine), and polymers made from monomers that contain (e.g., are modified with) carboxylic groups and/or amine groups. The polymer matrix can also be response to a biochemical stimulus, for example, by incorporation of an enzyme substrate, or an affinity ligand.

In some embodiments, the polymer matrix is gelatin, or a polymer comprising (hydroxyethyl)methacrylate (HEMA), ethyleneglycol dimethacrylate (EDMA), methacrylic acid (MAA), and/or acrylamide. The polymer matrix may be a polymer comprising (hydroxyethyl)methacrylate (HEMA), ethyleneglycol dimethacrylate (EDMA), and/or methacrylic acid (MAA). When it is desired that the chemical group that dimerizes through a cyclic bridge is a component of the polymer matrix, the polymer can contain a suitable derivative of (hydroxyethyl)methacrylate (HEMA), ethyleneglycol dimethacrylate (EDMA), methacrylic acid (MAA), or acrylamide that comprises the dimerisable chemical group, such as 2-(3,4,-dimethyl-2,5-dioxo-2,5-dihydro-1H-pyrrol-1-yl)ethyl methacrylate (DMIMA) described herein.

Suitable polymer matrices include copolymers of acrylamide and one or more additional monomers, such as those described herein or used to produce polymers described herein, such as vinyl acetate, poly(vinyl alcohol), poly(ethylene glycol) mono-methacrylate, poly(N-isopropylacrylamide) and N-isopropylacrylamide.

Particular compounds that comprise a chemical group that dimerizes through a cyclic bridge that can be employed in the holographic recording media according to an embodiment of the present invention comprise a maleimide group and are represented by the structural formula (I):

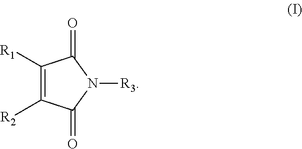

In formula (I):

R₁ and R₂ are each independently a C1-C10 alkyl, C1-C10 alkoxy, C3-C10 cycloalkyl, C6-C18 aryl, C6-C18 aryloxy, or R₁ and R₂, taken together with the carbon atoms to which they are attached form a saturated or unsaturated five or six-member hydrocarbon or heterocyclic ring, wherein a C1-C10 alkyl, C1-C10 alkoxy, C3-C10 cycloalkyl, C6-C18 aryl, C6-C18 aryloxy and a hydrocarbon or heterocyclic ring are each optionally substituted with COOH, —COX, —OH, —NR^{b}R^{c}, or a halogen; preferably, R₁ and R₂ are each independently a C1-C6 alkyl, or a C3-C6 cycloalkyl, each optionally substituted with —OH, —NR^{b}R^{c}, or a halogen; more preferably, R₁ and R₂ are each independently a C1-C6 alkyl, optionally substituted with —OH, —NR^{b}R^{c}, or a halogen.

R₃ is a linear or branched C1-C20 alkyl or a C3-C10 cyclic allyl having one or more (e.g., 1, 2, 3, 4, 5, 6, 7, 8, 9, or 10) carbon atoms optionally replaced by nitrogen or oxygen and/or optionally substituted with —COOH, —COX, —OH, —NR^{b}R^{c}, acrylate, methacrylate, acrylamide, —Si(R^{a})₂X, or Si(R^{a})₃; or R₃ is a poly(ethylene glycol) (PEG) with average molecular weight of less than or equal to 12000, wherein the hydroxyl group is optionally replaced by amines, —COOH, —COX, acrylate, methacrylate, acrylamide, —SR^{a}, —Si(R^{a})₂X or —Si(R^{a})₃; or R₃ is —(PEG)_{mol wt≦12000}C(O)O—NHS, or —(PEG)_{mol wt≦12000}C(O)O-sulfo-NHS. Preferably, R₃ is a poly(ethylene glycol) (PEG) with average molecular weight of less than or equal to 12000, wherein the hydroxyl group is optionally replaced by amines, —COOH, —COX, acrylate, methacrylate, acrylamide, —SR^{a}, —Si(R^{a})₂X or —Si(R^{a})₃; —(PEG)_{mol wt≦12000}C(O)O—NHS, —(PEG)_{mol wt≦12000}C(O)O-sulfo-NHS, or a linear or branched C1-C10 alkyl substituted with acrylate, methacrylate, or acrylamide; more preferably, R₃ is a linear or branched C1-C10 alkyl substituted with methacrylate.

X is a halogen (F, Cl, Br or I);

R^{a} is a hydrogen or a linear or branched C1-C10 alkyl, alkoxy or a C3-C10 cyclic alkyl; and

R^{b} and R^{c} are each independently a hydrogen or a C1-C6 alkyl.

Preferably, in formula (I), R₁ and R₂ are each independently a C1-C6 alkyl, or a C3-C6 cycloalkyl, each optionally substituted with —OH, —COOH, —COX, —NR^{b}R^{c}, or a halogen; and R₃ is a poly(ethylene glycol) (PEG) with average molecular weight of less than or equal to 12000, wherein the hydroxyl group is optionally replaced by amines, —COOH, —COX, acrylate, methacrylate, acrylamide, —SR^{a}, —Si(R^{a})₂X or —Si(R^{a})₃; —(PEG)_{mol wt≦12000}C(O)O—NHS, —(PEG)_{mol wt≦12000}C(O)O-sulfo-NHS, or a linear or branched C1-C10 alkyl substituted with acrylate, methacrylate, or acrylamide. More preferably, in formula (I), R₁ and R₂ are each independently a hydrogen or a C1-C6 alkyl, optionally substituted with —OH, —NR^{b}R^{c}, or a halogen; and R₃ is methacrylate.

Further examples of compounds that comprise a chemical group that dimerizes through a cyclic bridge that can be employed in the holographic recording media according to an embodiment of the present invention comprise a maleimide group and are represented by the structural formula (II):

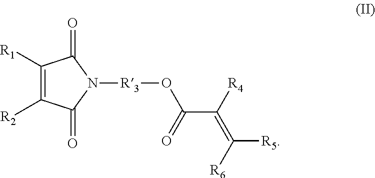

In formula (II):

R₁ and R₂ are defined above with respect to formula (I);

R′₃ is a linear or branched C1-C20 dialkyl or C3-C10 cyclic dialkyl, wherein the C1-C10 dialkyl or C3-C10 cyclic dialkyl has one or more (e.g., 1, 2, 3, 4, 5, 6, 7, 8, 9, or 10) carbon atoms are optionally replaced by nitrogen or oxygen, or R″3 is —C(O)—, —Si(R^{a})₂—, or —(PEG)_{mol wt≦12000}-; preferably, R′₃ is a linear or branched C1-C6 dialkyl, C3-C6 cyclic dialkyl or —(PEG)_{mol wt≦12000}-; more preferably, R′₃ is a linear or branched C1-C6 dialkyl; or —(PEG)_{mot wt≦}12000-;

R₄, R₅, and R₆ are each independently a hydrogen or a C1-C10 alkyl, C1-C10 alkoxy, C3-C10 cycloalkyl, C6-C18 aryl, C6-C18 aryloxy, each optionally substituted with —COOH, —COX, —OH, —NR^{b}R^{c}, or a halogen; preferably R₄ and R₅ are each independently a hydrogen or a C1-C6 alkyl.

Preferably, in formula (II), R₁ and R₂ are each independently a C1-C6 alkyl, or a C3-C6 cycloalkyl, each optionally substituted with —OH, —NR^{b}R^{c}, or a halogen; R′₃ is a linear or branched C1-C6 dialkyl or C3-C6 cyclic dialkyl; R₄, R₅ and R₆ are each independently a hydrogen or a C1-C6 alkyl.

In another embodiment, in formula (II), R₁ and R₂ are each independently a hydrogen or a C1-C6 alkyl, optionally substituted with —OH, —NR^{b}R^{c}, or a halogen; R′₃ is a linear or branched C1-C6 dialkyl; and R₄, R₅, and R₆ are each independently a hydrogen or a C1-C6 alkyl.

When the compound of formula (II) is a component of the polymer matrix, the polymer matrix can comprise the structure (IIa):

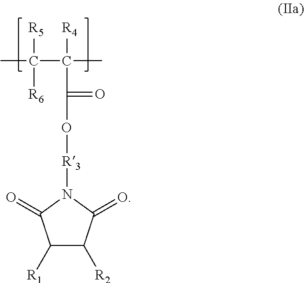

R1, R2, R′3, R4, R5 and R6 are as defined for formula (II).

In a particular example, the compound of formula (II) is a compound represented by structural formula (III):

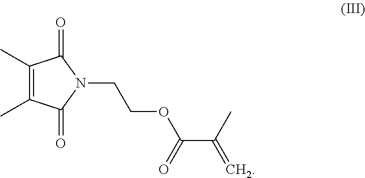

When the compound of formula (III) is a component of the polymer matrix, the polymer matrix can comprise the structure (IIIc):

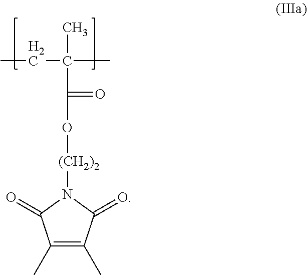

In one embodiment, the holographic recording media of the present invention comprises a compound of formula (II), and a polymer matrix, selected from the polymers of (hydroxyethyl)methacrylate (HEMA), ethyleneglycol dimethacrylate (EDMA), or methacrylic acid (MAA). Values and preferred values of the variables in formula (II) are as defined above.

Upon dimerization via photocycloaddition, the compound of formula (I) forms a dimer represented by structural formula (IV):

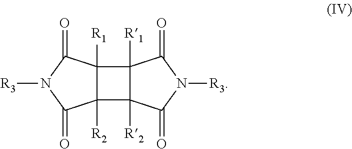

In formula (IV), variables R′₁, and R′₂ each independently take values and preferred values of variables R₁ and R₂, as defined above for formula (I). Variables R₁, R₂.

and

R₃ take values and preferred values as defined above for formula (I).

Similarly, upon dimerization via photocycloaddition, the compound of formula (II) can form a dimer represented by structural formula (V).

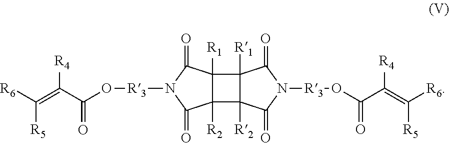

In formula (V), values and preferred values of the variables are as defined above for formula (II). Variables R′₁ and R′₂ each independently take values and preferred values of variables R₁, and R₂, as defined above for formula (II).

When the compound of formula (II) is a component of the polymer matrix, the polymer matrix can comprise the structure (Va) after dimerization by photocycloadditon:

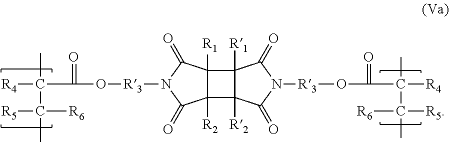

R′₁, and R′₂ each independently take values and preferred values of variables R₁ and R₂, as defined above for formula (II). R1, R2, R′1, R′2, R′3, R4, R5 and R6 are as defined for formula (II).

In a particular example, the dimer of structural formula (V) is represented by structural formula (VI):

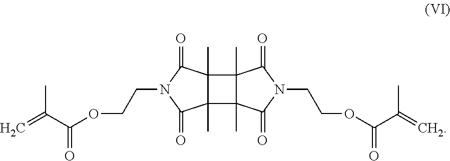

When the compound of formula (VI) is a component of the polymer matrix, the polymer matrix can comprise the structure (VIa) after dimerization by photocycloadditon:

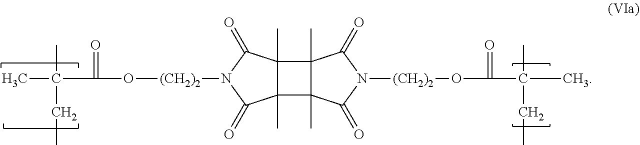

R1, R2, R′3, R4, R5 and R6 are as defined for formula (II).

The polymer matrix can also comprise adducts of formula D-FG, wherein D is a second dimerisable chemical group that can be any of the dimerisable groups described above, for example, the dimerisable chemical group represented by structural formula (I) and FG is a functionality conferring group.

The polymer matrix can also comprise functional dimeric structures L-D₁-D₂-FG, wherein L is absent (when the functional dimeric structure is not covalently attached to a polymer matrix) or a linking group or a bond attaching the functional dimeric structure to a polymer matrix, D₁ is a dimerizable chemical group that has dimerized with the adduct D₂-FG via photocycloaddition to form a cyclic bridge. D₁ and D₂ can be the same or different. Typically, L is a linking group a bond, that is, typically, the functional dimeric structure is a pendent group of a polymer matrix.

A functionality conferring group is a chemical group that when incorporated in the holographic recording media of a holographic sensor according to an embodiment of the present invention, enables an new or changed response of the holographic sensor to an external stimulus. Suitable, functionality conferring groups include, for example, ligands, antigens, antibodies, enzymes, proteins, chelators, receptors, stimulus responsive oligomers or stimulus responsive polymers.

Particular adducts are represented by structural formula (VII):

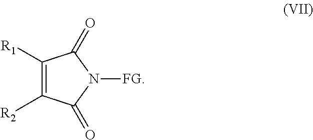

Variables R1 and R2 take values and preferred values as defined above for formula (I).

Adducts can be reacted with dimerizable chemical groups as described above via photocycloaddition to incorporate functional dimeric structures into the polymer matrix, wherein the dimerisable groups can be free or covalently attached to the polymer matrix.

When the compound of formula (VII) is dimerized via photocycloaddition with a dimerisable chemical group D-L, the polymer matrix can comprise the functional dimeric structure represented by formula (VIIa):

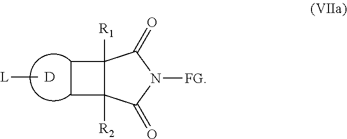

L is absent (in the case of a free, that is, not covalently attached dimerisable group) or a bond covalently attaching the dimerisable chemical group D to a polymer matrix. Variables R1 and R2 take values and preferred values as defined above for formula (I).

In a particular example, the functional dimeric structure of formula (VIIa) is part of a polymer matrix and is a structure represented by structural formula (VIIb):

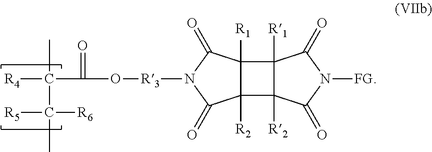

R′₁, and R′₂ each independently take values and preferred values of variables R₁ and R₂, as defined above for formula (II). R1, R2, R′3, R4, R5 and R6 are as defined for formula (II).

In a more particular example, the functional dimeric structure of formula (VIIb) is a structure represented by structural formula (VIIc):

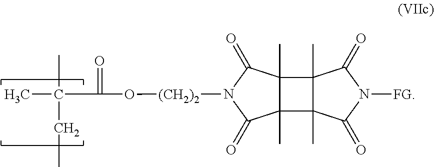

A further particular dimeric structure that is part of a polymer matrix is represented by structural formula (VIII):

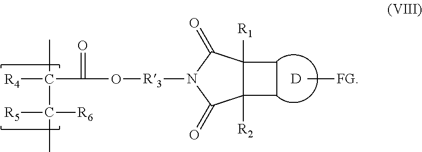

Variables R1 and R2 take values and preferred values as defined above for formula (I). R′3, R4, R5 and R6 are as defined for formula (II).

The functionality conferring group FG in structural formulas (VII), (VIIa), (VIIb), (VIIc) and (VIII) can be a ligand, antibody, enzyme, protein, chelator, receptor, stimulus responsive oligomer or stimulus responsive polymer.

More typically, FG in structural formulas (VII), (VIIa), (VIIb), (VIIc) and (VIII) is a group that targets molecules that include cis-diol moieties.

Also, more typically, FG in structural formulas (VII), (VIIa), (VIIb), (VIIc) and (VIII) is a group that targets a monosaccharide or disaccharide.

Even more typically, FG in structural formulas (VII), (VIIa), (VIIb), (VIIc) and (VIII) is a group that targets a monosaccharide.

Yet even more typically, FG in structural formulas (VII), (VIIa), (VIIb), (VIIc) and (VIII) is a group that glucose.

Preferably, FG in structural formulas (VII), (VIIa), (VIIb), (VIIc) and (VIII), is a phenyl boronic acid.

More preferably, FG in structural formulas (VII), (VIIa), (VIIb), (VIIc) and (VIII) is represented by structural formula (IXa) or (IXb):

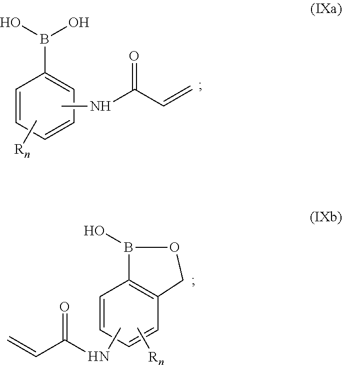

wherein n is 0, 1 or 2, and each R is independently hydrogen, halogen (preferably, F or Cl), C1-C6 alkyl, NO₂, cyano, COOalkyl, COalkyl or CF₃.

In a preferred embodiment, the functional dimeric structure comprises a substructure represented by structural formula (X):

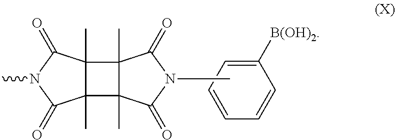

Other functionality conferring groups FG that can be coupled to a maleimide group or other dimerisable chemical group to form an adduct are provided in WO03/087899, WO04/081624, WO06/079843 and WO07054689, all of which are herewith incorporated by reference in their entirety.

### Sensor and Detection Methods According to Example Embodiments of the Present Invention

One embodiment of the present invention is a holographic sensor comprising a holographic recording media according to an embodiment of the present invention and at least one image recorded in said holographic recording media as diffraction fringes. The diffraction fringes comprise a dimeric compound that includes a cyclic bridge. A physical or a chemical property of the holographic recording media varies in response to an external stimulus, as described above.

The holographic sensor can have any desired shape or form. For example, the sensor can be in the form of a flat film, with or without a support layer, flakes, beads, spheres, balloons, cubes, and the like. Suitable methods for preparing a variety of forms of sensors, including milling, extrusion and the like are well known in the art. Certain types of sensors, such as beads, flakes, spheres, balloons and the like, can be present in a colloid.

The holographic sensor according to an embodiment of the present invention can further include a support layer that supports the holographic recording media with at least one image recorded therein. Typical support layers are transparent or opaque, flexible, semi-rigid or rigid and may be of glass, polymers, in particular plastics, paper of any kind, paper board, fibrous materials, metal laminates of paper or metal laminates of plastics optionally containing both materials in combination, and laminates of paper and plastics with other appropriate materials such a metal or wood. Such supports generally have an appropriately shaped surface to support the holographic recording media with at least one image recorded therein, such as a planar surface or other appropriately shaped surface. Example support materials are selected from glass, plastic, metal or a combination of metal and plastic (for example, aluminized polyester sheets). In some embodiments, the support layer is triacetyl cellulose (TAC) film or polyethylene terephthalate (PET) film.

Another embodiment of the present invention is a method of detecting an external stimulus comprising applying an external stimulus to a holographic sensor according to an embodiment of the present invention, as described above, and detecting at least one readout signal.

Various examples of the external stimuli are given in the preceding sections. The readout signal is based on a change in a physical or chemical property of the holographic recording media and may be selected from a variation in reproduction wavelength of at least one image recorded in the holographic recording media, appearance of an additional image recorded in the holographic recording media, and disappearance of at least one image recorded in the holographic recording media.

In particular embodiments, the external stimulus is selected from humidity, acidity (pH), metal ions, glucose, antibodies and organophosphates, and the readout signal is selected from a variation in reproduction wavelength of at least one image recorded in the holographic recording media, appearance of an additional image recorded in the holographic recording media, and disappearance of at least one image recorded in the holographic recording media.

Certain sensors of the present invention can be used as a security device. For example, an additional holographic image can appear when the sensor is exposed to a desired stimulus, such as IR, visible or UV light. The appearance of the additional holographic image provides an indication that the sensor and any goods to which the sensor is attached are authentic. If desired a recorded holographic image can change color (due to change in the reproduction wavelength) in response to stimulus, such as a change in humidity, oxygen, glucose, pH, metal ion or carbon dioxide/hydrogen sulfide concentration (e.g., due to exposure to air), or lipids (e.g., lipids contained on human skin). Such sensors can be incorporated, for example, into packaging to ensure the integrity of the package before purchase or consumption by a consumer. Similarly a violation of the sensor integrity (e.g., due to a break in a package) can result in disappearance of a recorded image, due to a shift in replay wavelength from the visible spectrum to the IR or UV spectrum or due to chemical reaction of the holographic recording media with atmospheric gases (e.g., oxygen, carbon dioxide, etc.).

The security device can exhibit a form useful in the known applications of security elements. For example, the security device can be a label, a patch, a stripe, a thread, or the like, and can have any desired shape, as appropriate for the intended application. Security devices in the form of labels, patches, stripes, threads and the like can be applied to the surface of an object to secure the object. Therefore, the security device according to an embodiment of the present invention can be applied to the surface of an object using any suitable methods or means, such as using an adhesive, a pressure-sensitive adhesive, a hot-melt adhesive, a reactive or partly reactive hot-melt adhesive or any suitable combination thereof. Adhesives are generally selected to ensure that a permanent bond to the surface of the object is achieved. In this way it is possible to avoid the later illicit removal of the security device from the surface of the object. Methods known as tamper evident systems can be used to achieve destruction of the security device in the event that illicit removal is attempted. Any adhesives used should also not affect the performance of the multiple security means. Such processes and the materials used as adhesives are very well-known in the art and need no further description herein.

The security device (e.g., in the form a label, a patch, a stripe, a thread, or the like) can be applied to an object using any suitable method, such as foil blocking or foil stamping. Foil blocking and foil stamping are particularly useful for applying the security device to, for example, a plastic card (e.g., credit card, bank card), security document, and the like. The security device can be applied to an object using a thermo-transfer process by using a transparent carrier as a transfer carrier and/or as a release protection foil during the thermo-pressure process. The transparent carrier can be peeled off after the application or can stay on top as a protection layer. In the case of keeping it on top of the security element as a protection layer, usually a good adhesion to the substrate is achieved. In some embodiments, the transparent carrier in general exhibits a thickness of about one micrometer to about a few millimeters, especially from 1 μm to 800 μm, preferably from 5 to 300 μm and in particular from 10 to 100 μm. The material thereof is, in most cases, a temperature stable polyester (e.g., PET) foil. Such foils can be used in a microperforated version to prevent peeling without damaging of the security element. The microperforation can be done by laserperforation, by mechanically punching, by spark erosion or using any other suitable method.

When the security device according to an embodiment of the present invention is configured as a label, a patch, a stripe, a thread, or the like, it can be applied in many different designs and application technologies. Furthermore, since such security devices are usually thin (down to 5 to 50 μm thick) and can be stored on rolls, the security device can be applied to an object with high quality and with high speed. For example, security device labels may be conveniently located on a roll which comprises at least one thermostable release layer that is peeled off the security device label after application to the surface of the object to be secured.

By peeling off the release layer of the security device, the surface thereof is free to be exposed to an external stimulus, such as to the application of humidity, water, chemicals, gases, etc. A perforated or porous release layer may be maintained on the security device, since it is able to transmit the external stimuli mentioned above to the volume hologram. External stimuli like temperature, electrical charge, electrical potential, pressure, magnetism, etc., do not require removal or the release layer or a perforated release layer, since usually the release layer is very thin and does not negatively influence the changes within the holographic structure caused by these stimuli. In these situations, the release layer may act as a protective layer on the security device.

In general, security elements exhibiting a protective layer, either porous or not, provide very good protection against abrasion and scratching. Protective layers bearing microperforations may also prevent removal of the protective layer without damaging the security element itself (so called tamper evident self-destruction behaviour). When used, protective layers are selected that are thin and flexible enough to allow volume changes in the volume hologram structure.

The security device according to embodiments of the present invention may also be integrated into an object to produce a secured product, for example, of the laminate type or of the injection-mould type, i.e., the security device is a part of the product.

For example, the security device can be incorporated into an injection-moulded plastic part, or a laminated structure on a base of polymer foils, polymer and paper, or cotton based sheets and the like. The lamination process should be performed under temperature control in order to avoid destruction of the volume hologram, or, especially when polycarbonate polymers are used, to avoid the yellowing tendency of these polymers when exposed to temperatures of about 200° C. over a longer period. Such yellowing is especially harmful when security documents are produced which should have a life-time guarantee of at least 10 years, e.g., ID-cards, driver-licenses, passports, etc.

When the security element according to an embodiment of the present invention is integrated in a laminated or injection moulded security product, external stimuli like temperature, electrical charge, electrical potential, pressure, magnetism, etc., may be applied to the security product and cause a change within the volume hologram as long as at least one of the layers or protective layers on one either one or both sides of the security element is thin and flexible enough in order to allow volume changes in the security element. When external stimuli like humidity, water, chemicals, gases, etc., are to be detected, at least one of the layers on each side of the security element within the security product allows the external stimulus to contact the volume hologram (e.g., be permeable to the external stimulus). This permeability may be achieved, for example, by perforation, especially in form of microholes, or by using a substrate having lateral or horizontal channels therein. Microholes may be produced by laser beams at a very high speed, e.g., by CO₂ lasers, Nd:YAG lasers and UV-lasers at different wavelength, by spark erosion or any other suitable method. Such microholes may exhibit high aspect ratios or may have a conical form as desired. Similarly, the above mentioned channels in substrates may be produced mechanically, chemically, or through other known techniques.

The security device may also be applied to an object, such as a product, in combination with a window, so that the holographic image can be observed from either one or both sides of the security device. When applied in a window structure, the security device according to an embodiment of the present invention can be covered on either one or both sides with a protective layer. At least one of these layers is permeable (e.g., porous) to the external stimulus applied thereto. Thus, embodiments in which the security device is covered on only one side with a protective layer is preferred when humidity, water, chemicals, chemical solutions, gases, etc., are used as external stimuli.

A security device as described herein can comprise an additional security element, if desired. For example, the security device can comprise a holographic sensor as described herein and one or more of a water mark, a laser engraving, a planchette, a fibre, a fluorescent element (e.g., particle or fibre), an IR or UV active colorant, a magnetic element, an electrically conductive element, an optically variable pigment, an LCP pigment, a chemical additive observable by irradiation with light of a particular wavelength or by chemical reaction or by manipulation of the substrate, a DNA- and/or bio-coding material, an organic or inorganic taggant, a hologram, a kinegram, a radio frequency identification (RFID) element, an optically variable printing and/or an optically variable system of optically variable pigments, an optically variable thin film structure and/or liquid crystal polymers, microtext, guilloches, a photoluminescent element, an electroluminescent element, a photochromic element, a thermochromic element, a hydrochromic element, a tribochromic element, a piezochromic element, and the like.

Products which may be secured and/or provided using the security device according to an embodiment of the present invention include banknotes, passports, identification documents, smart cards, driving licenses, share certificates, bonds, cheques, cheque cards, tax banderols, postage stamps, tickets, credit cards, debit cards, telephone cards, lottery tickets, gift vouchers, packaging materials, for example pharmaceutical packaging materials, decorative materials, branded products, or any other object or product which is desirable to secure, e.g., household appliances, spare parts, shoes, clothes, sporting goods, computer hardware, computer software, recordable media, such as DVDs, pharmaceuticals, cosmetics, spirits, cigarettes, tobacco, and the like.

In another embodiment, the sensor can be employed for detecting biological material, such as nucleic acids, proteins, mono-, oligo- and polysaccharides, and liposaccharides. Sensors of this type can be prepared and used by a variety of methods. For example, as described above, a means to detect a biological analyte, such as a ligand and/or receptor cognate to the analyte to be detected, is incorporated into the holographic recording media. Binding of the analyte then changes a physical or chemical property of the media, producing a readout signal. Many biological analytes themselves can change the physical or chemical properties of the holographic recording media of the sensor upon coming into contact with the holographic recording media, thereby generating a readout signal.

The holographic images, including static images and/or stimulus-responsive images can be observed in any suitable manner, such as by the human eye (with or without the use of spectacles, contact lenses, magnifying lenses, polarizing filters and the like) or using any suitable device for detecting the image, such as optical enhancing devices and/or optical detectors.

For example, a first holographic image exhibited by the security element can be observed at a first viewing angle and a second different holographic image can be observed at a second viewing angle that differs from the first viewing angle. The second viewing angle may be achieved, for example, by tilting or otherwise changing the position of the security element relative to the observing unit (human eye, device for detecting the image), whereas the viewing position of the observing unit is maintained, or by changing the viewing position of the observing unit, whereas the position of the security element is maintained, for example. Of course, both the viewing position of the observing unit as well as the position of the security element may be changed, if desired. In another example, the two images can be detected using separate observing units, such as two optical detectors that are at different viewing positions, or optical detectors of different types.

If desired, one or more further images can be recorded in the holographic recording media and they can be observed at one or more further viewing angles that are different from the first and second viewing angles. These further images may be revealed by moving the interactive security element according to an embodiment of the present invention using any suitable movement, e.g., up and down movement, circular movement or any other movement relative to the observing unit, by movement of the observing unit or by movement of the light source. The further images which may be observed at these further viewing angles are due to the action of the volume hologram itself, since it is possible to record a number of images in a volume hologram regardless of whether it is responsive to stimuli or not. Preferably, such further images can be observed prior to the application of any stimulus.

For the purpose of this description, the term “observing unit” is meant to be a person or an optoelectronic verification device, e.g., a camera system or a hand-held optical detector. Such an observing unit exhibits, a particular viewing position relative to the position of the security element, i.e., its viewing position is directed to the security element so that an observation of the security element is possible.

For the purpose of this description, the term “different image” means, that the images which may be observed at said first and/or second viewing angle are different in color and/or intensity and/or brightness and/or object and/or position and/or orientation and/or size and/or apparent depth and/or perspective and/or parallax. Therefore, not only holographic representations of different objects, e.g., bar-codes, logos, trademarks, etc., are regarded as being different images, but also for instance a particular logo, which alters in colour, the intensity of the colour, its brightness, its position, its orientation, its size and/or its apparent depth on the security element, due to the application of at least one external stimulus.

Depending on how the images (one or more stimulus-responsive image and/or static images) are arranged, the changing image may be detected by the unaided human eye or with the assistance of magnifying lenses, microscopes, lenticular lenses, polarizing filters, diffractive structures, wavelength filter elements, light enhancing systems, and the like, or by optical detectors such as spectrophotometers, spectrum analysers, CCD-sensors, CMOS-sensors, OCR-readers, bar code readers, cameras and image recognisers, or any suitable combination of the foregoing. The image may be an image of, for example and without limitation, one or more of: an alphanumeric or similar character, microtext, a picture, a photo, a bar code, a physical object, a logo, a trade mark, a computer generated picture, a computer generated object and projections thereof. The image may include or consist of a mirror or reflective surface. Multiple stimulus-responsive and/or multiple static images can be present as desired. The change in the stimulus-responsive image may be reversible, partly reversible or irreversible.

### Methods of Manufacturing of the Holographic Recording Media and Sensors According to Embodiments of the Present Invention

In one embodiment, the present invention is a method of manufacturing a holographic sensor, comprising (a) manufacturing or providing a holographic recording media that comprises (i) a polymer matrix, and (ii) a chemical group that dimerizes by forming a cyclic bridge through photocycloaddition; and (b) recording at least one image as diffraction fringes in said holographic recording media. The diffraction fringes comprise a dimer of the chemical group that is dimerized through the formation of a cyclic bridge. The holographic recording media responds to an external stimulus by generating at least one readout signal.

A further embodiment of the present invention is a method of manufacturing a holographic sensor comprising recording at least one holographic image as diffraction fringes in a holographic recording media, the holographic recording media including (i) a polymer matrix; and (ii) a plurality of dimerisable chemical groups that dimerize by forming a cyclic bridge through photocycloaddition; wherein the diffraction fringes comprise a plurality of dimeric structures that include a cyclic bridge and the holographic recording media responds to an external stimulus by providing at least one output signal.

If desired, following recording according to the methods described above, undimerized chemical groups that dimerize by forming a cyclic bridge can be modified or derivatized to reduce the likelihood that they will dimerize. For example, when the dimerisable compound is of Formula I, II or IIA, undimerized compounds can be modified or deriviatized to reduce the double bond in the maleimide group or to modify the substituents R₁ and/or R₂. Reduction of the double bond can accomplished, for example, by double substitution of the carbon atom to which R₁ or R₂ is bonded, to produce a compound in which, for example, R₁ is not hydrogen and another substituent is bonded to the carbon atom to which R₁ is bonded. This procedure can increase the differential of refractive index between the fringes and the polymer matrix. Another approach to increase the differential of refractive index between the fringes and the polymer matrix is to modify the polymer matrix to include suitable pendent groups following recording. Suitable methods for adding pendant groups to polymers are well known in the art and any suitable method can be used.

Further, if desired, after recording of one or more holographic images, unreacted (i.e., groups that did not dimerize during recording) dimerisable cyclic groups remaining in the medium, particularly in the dark fringe areas, can be utilized to further improve the properties of the photopolymer holograms. Specifically, the holographic recording media can be cured, for example, by applying actinic radiation to dimerize part or all of the remaining unreacted dimerisable groups. The unreacted dimerizable groups can be dimerized in a partially swollen state of the polymer matrix of the holographic recording media. In the case of unreacted dimerisable chemical groups that are covalently attached to the polymer matrix, the dimerization in the curing step leads to additional crosslinking (also referred to herein as “photo-crosslinking”) that imparts rigidity to the swollen hologram. Such a holographic sensor when dried completely does not collapse to its initial thickness, and, thus, a holographic image associated with diffraction fringes of different spacing results. Typically, when the post curing step is performed in a partially swollen state of the holographic recording media and the holographic image was recorded in a dry or relatively less swollen state, the diffraction fringes will be spaced further apart leading to a holographic image having a longer (larger) replay wavelength than the holographic image that was recorded in the dry state or less swollen state of the holographic recording media. Thus, using post curing can result in the holographic sensor exhibiting a holographic image in the visible spectrum, even though the hologram was recorded using UV laser light.

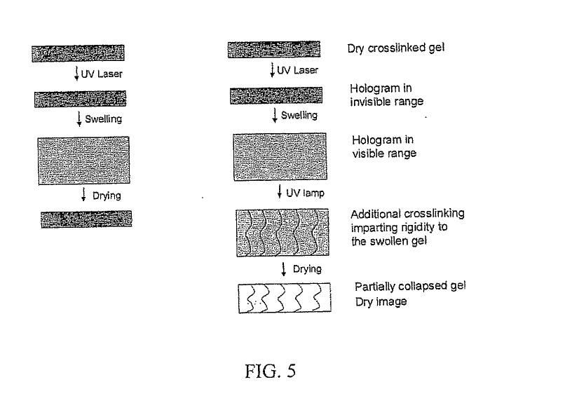

FIG. 5 provides a schematic representation comparing a method for preparing a photopolymer hologram that does not include post-curing of residual dimerisable groups (left) with a method for preparing a photopolymer hologram that includes post-curing of residual dimerisable groups (right), and an examplary method using post-curing is provided in Example 6.

Further, if desired, dimerizable chemical groups can be reacted with adducts as defined above to form functional dimeric structures. These dimerizable chemical groups can be groups in the polymer matrix (diffused and/or covalently bonded to the polymer matrix) prior to any recording of a holographic image, or unreacted dimerisable chemical groups after recording of one or more holographic image(s). After recording, these unused photo-dimerisable groups remain particularly in the non-fringe and dark fringe areas.

Dimerizing the dimerizable chemical groups and adducts can comprise (a) dissolving the adducts in a solvent to form a solution, (b) immersing a holographic recording media or holographic sensor in the solution, and (c) applying actinic radiation, typically UV radiation >300, where (a) and (b) are performed to cause the adducts to diffuse into the polymer matrix and (c) is typically performed after (1) establishment of equilibrium concentration. In one embodiment, uniform intensity of actinic radiation is applied to cause photocycloaddition of the adduct with the dimerizable chemical groups of the polymer matrix. Additionally, dimerizing involves removing any unreacted adducts from the polymer matrix after applicaiton of the actinic radiation, for example by washing the polymer matrix.

Incorporation of functionality by this method can be done at any stage in the process of making the hologram sensor, depending on the requirements. The incorporation may be carried out before any final curing in which unreacted dimerisable chemical groups are crosslinked. Further, recording of the hologram via dimerisation to or from diffreaction fringes and coupling of the adduct with dimerisable chemical groups may be carried out simultaneously, the extent of functionality that is incorporated being controlled, for example, by the amount of the adduct added to the solution, and subsequently diffused into the matrix, and the density of dimerisable chemical groups throughout the polymer matrix. In some cases it can be preferable to carry out the incorporation of the adduct after the recording of the hologram. In this case the majority of the unreacted dimerisable chemical groups are located in the dark fringes of the polymer, where crosslinking due to the recording of holographic image(s) is weakest. This enables the functionality to be incorporated primarily into the dark fringes which can be preferred for analyte detection where effective swelling of the matrix is required. In some cases, however, it may be desirable to add the adduct before recording the hologram. For example, a linear polymer may be prepared from monomers and the polymer coated onto a substrate from solution. The solution may also comprise the adduct. The coated polymer film comprising the adduct may then be exposed to UV to couple the adduct to the polymer chain before recording of a holographic image.

Further, different adducts may also be incorporated at different stages in the method of manufacturing or preparing a holographic sensor; for example, a first adduct may be added prior to any recording of holographic image(s) and a second adduct after recording of one or more holographic images.

Additional methods for incorporating functionality conferring groups into a polymer matrix include (a) linking a polymerisation initiators (e.g., ATRP or NMRP) to a functionality conferring group using methods known in the art and (b) initiation of polymerisation of a polymer that forms the polymer matrix using the polymerisation initiator linked to the functionality conferring group. In this way, when polymerisation is initiated by the initiator this molecule, each polymer chain will have the functionality conferring group as an end group.

In one embodiment, the methods for manufacturing and preparing a holographic sensor, as described above, comprise polymerizing a monomer, thereby creating a polymer matrix. Examples of hydrophilic and hydrophobic polymer matrices are given above. One of ordinary skill in the polymer art will readily understand what types of monomers are suitable. One preferred embodiment of the polymer matrix is a hydrogel [e.g., polymers and copolymers comprising poly(vinyl alcohol), sodium poly(acrylates), poly(methacrylates), poly(acrylamides) and the like which have an abundance of hydrophilic groups]. The dimerisable compounds employed by the holographic recording media according to an embodiment of the present invention (for example, the compound of formula (I), above) can be admixed with the monomers before manufacturing the polymer matrix, or added into the matrix after polymerization (e.g., by diffusion).

In some embodiments, the polymer matrix is prepared using a difunctional polymerizable compound, such as a monomer that comprises a dimerisable moiety and a polymerizable moiety (e.g., a compound of formula (II)), and, if desired, one or more other monomers. Such difunctional compounds can be prepared using any suitable methods, such as the methods described herein for the preparation of DMIMA or suitable modifications of the method. Generally, one or more other monomers are used in addition to a difunctional polymerizable compound to prepare the polymer matrix.

Manufacturing the polymer matrix can be achieved by any suitable polymerization technique, such as free radical photopolymerization by exposing the monomers to actinic radiation (e.g., UV) in presence of a photoinitiator. Examples of photoinitiators that can be used include 2-dimethoxy-2-phenyl acetophenone (DMPA) and Irgacure® (Ciba). Polymerization can also be accomplished by free radical thermal polymerization of monomers in the presence of a free radical initiator, cationic polymerization using a cationic initiator or anionic polymerization using an anionic initiator. Examples of free radical initiators that can be used include 2,2-Azobis(2-amidinopropane) dihydrochloride (AIBA) as a cationic initiator; ammonium persulfate (APS), sodium persulfate (SPS) and potassium persulfate (KPS) as anioinic initiators; and 2,2-Azobisisobutyronitrile (AIBN) as a nonionic initiator. Polymerization can also be accomplished by controlled free radical polymerization, and living polymerization (e.g., ATRP, NMRP, etc.) can also to be used to prepare polymers with desired chain lengths. For example, a combination of alkyl halide, metal halide, and ligand, can be used to initiate polymerization. Suitable initiators are well-known in the art and one of ordinary skill in the art will be able to select an initiator without undue experimentation. (See, e.g., www.sigmaaldrich.com/Area_of_Interest/Chemistry/Materials_Science/Polymerization_Tools/Free_Radical_Initiators.html.)

A person of ordinary skill in the art can choose a hydrophobic or hydrophilic monomer/polymer and can incorporate photo-dimerizable groups (dimerizable chemical groups) by appropriate polymerisation technique/polymer modification reactions. Hydrophobic polymers are, for example, commercially available from Sigma-Aldrich (see http://www.sigmaaldrich.com/materials-science/material-science-pro ducts.html?TablePage=16372120).

In certain embodiments, polymer matrix may be further cross-linked using the available dimerisable chemical groups, covalently attached to the polymer matrix.

Recording of the holographic image typically includes irradiating the holographic recording media with a laser, thus affecting dimerization of the dimerisable compounds present in the media. The pattern of dimerization of the compounds follows the interference pattern, thus creating areas of the media having refractive index different from the areas that were not exposed to light or radiation, where destructive interference took place. Such areas of dimerization form interference fringes. If desired, two or more images can be recorded in the media. Additionally, the image can be recorded in any desired state of the media, such as a dry state, a hydrated state, or at a desired pH. For example, in some embodiments, an image is recorded in the dry state and a second image is recorded in the hydrated state.

Further, recording can be performed in the presence of photoinitiators and/or photosensitizers if desired. One of ordinary skill in the art will be able to select a suitable photosensitizers without undue experimentation. Examples of photoinitiators are given above. Examples of photosensitizers include dyes such as thioxanthone, acetophenone, benzophenone, Michler's ketone (4,4′-bis(dimethylamino)benzophenone), and benzil ((C6H₅CO)₂). Depending on the presence of a photosensitizer dye, and depending on the particular dimerisable compound used, the holographic image recording according to one embodiment can be carried out at a suitable wavelength, such as from about 235 nm to about 650 nm, preferably about 250 nm to about 415 nm. A photosensitizer can be present during polymerization and/or recording. If a photosensitizer is not present during recording, generally a stronger source of radiation (e.g., a stronger UV laser) will be used when a photosensitizer is present. It is to be understood that any suitable initiator, such as ionic initiators (e.g., cationic initiators) can be used to prepare the polymer matrix.

Further, some embodiments of a holographic sensor exhibit a visible holographic image in the absence of an external stimulus, for example, an analyte, and the holographic sensor may provide a visible holographic image of a changed color or a different holographic image on exposure to an external stimulus, for example, an analyte. Pre-swelling of the polymer as exemplified in Example 8, is one possible way of achieving this. An alternative way is to record images in the matrix by using a visible light frequency. A dry hologram recorded in this way may be recorded in the blue green region of the spectrum, and optionally recorded in the green region where the eye is more sensitive. When the hologram interacts with the analyte, swelling of the matrix moves the replay wavelength to the red. Breath sensors are an example of this. Thus, sensitisers suitable for this application are sensitive in the blue green region and in some applications are preferred. However, some polymer matrices may contract in a presence of an external stimulus, for example, analytes. In this case, sensitisers and/or photo-initiators that are sensitive in the red region may be preferred for certain applications.

Another embodiment of the present invention is a method for recording a holographic image. The method comprises controlling (1) the fraction of dimerization of dimerisable chemical groups that form dimeric structures by photocycloaddition and (2) retention of spatial positions of the dimeric structures, relative to each other and to dimerisable chemical groups that did not dimerize, to record the holographic image and enable a controlled observable response of the recorded holographic image, in a later presence of an external stimulus.

A related embodiment of the present invention is a method for recording a holographic image comprising (a) dimerizing dimerisable chemical groups through photocycloaddition to form dimeric structures in response to photons representing the holographic image, and (b) retaining spatial positions of the dimeric structures, relative to each other and to dimerisable chemical groups that did not dimerize, to retain a recorded holographic image, in a manner enabling a controlled observable response of the recorded holographic image as a function of the dimerizing and retaining in a later presence of an external stimulus. The photons representing the holographic image correspond to variations in light intensity formed by interference in the medium of coherent light reflected from an object (of which a holographic image is to be recorded) and a coherent reference beam.

A further related embodiment of is a method for recording a holographic image comprising (a) retaining spatial positions of dimerisable chemical groups and dimeric structures, wherein the dimerisable chemical groups form dimeric structures through photocycloaddition; and (b) dimerizing the dimerisable chemical groups through photocycloaddition to form dimeric structures in response to photons representing the holographic image, to retain a recorded holographic image, while (c) enabling a controlled observable response of the recorded holographic image, as a function of the dimerizing and retaining in a later presence of an external stimulus.

Examples of suitable and preferred dimerisable chemical groups that can be used in the above described methods for recording a holographic image are provided above. Controlling the fraction of dimerization can be achieved, for example, by controlling the laser light exposure for chosen dimerisable chemical groups and/or by controlling the spatial density distribution of dimerizable chemical groups. The dimerizable chemical groups can be compounds that are not covalently bonded to a polymer matrix or compounds that are covalently bonded to a polymer matrix. In either case, the polymer matrix restricts the spatial mobility of the dimerisable chemical groups and subsequently of dimeric structures formed from these dimerisable chemical groups. Further, in the case of covalently attached dimerizable chemical groups, the spatial mobility can be controlled for a given dimerisable chemical group by the length of a linking group, that is, a group linking the dimerizable chemical group to the polymer matrix. Swelling a polymer matrix that comprises dimerisable chemical groups and/or dimeric structures changes the spatial positions of dimerizable chemical groups and dimeric structures in the polymer matrix. In this context, controlling retention spatial positions of the dimeric structures, relative to each other and to dimerisable chemical groups that did not dimerize, can be achieved, for example, by swelling a polymer matrix that comprises the dimerisable chemical groups to a chosen swollen state and maintaining the chosen swollen state during dimerization of the dimerisable chemical groups to form dimeric structures. Dimerization and the spatial density distribution of dimerizable chemical groups and dimeric structures formed by dimerization are controlled to enable a controlled observable response of the recorded holographic image, in a later presence of an external stimulus.

Regions of high and low density of dimers are formed by photocycloaddition reactions in response to the variation of light intensity in the recording media formed by the interference fringes of the light beams recording the hologram. These regions form the diffraction fringes of the recoded hologram which comprise a variation in density of dimers throughout at least part of the volume of the medium, where regions of relatively high density of dimers correspond to regions of constructive interference (bright fringes) and regions of relatively low density of dimers correspond to regions of destructive interference (dark fringes). By the fringes comprising dimeric groups is thus meant those dimeric structures formed during the recording of the hologram.

Further, polymers incorporating functionality conferring groups, for example, receptors, may be used as polymer matrix or as part of a polymer matrix. These may be prepared by incorporating co-monomers comprising receptors in the polymer chain, that is, receptors for analytes may be incorporated into the polymer matrix during polymerisation of the polymer. For example, receptor groups such as 3-acrylamidophenylboronic acid (3-APB) may be coupled to a vinyl group to form a monomer that can copolymerise with other acrylic co-monomers and thus become incorporated into the polymer matrix. An example is provided in Example 6. Monomers comprising receptor groups may have the vinyl group linked directly to the receptor or indirectly via a chain (usual selection). Monomers comprising receptors may be copolymerised with monomers comprising dimerizable cyclic groups, simple monomers such as acrylic monomers e.g., methacrylamide, methacrylic acid, hydroxyethylmethacrylate, and cross-linkers known in the art, using known polymerisation techniques. The polymer may be formed directly by photo-initiation of the monomer mixture on a substrate such as glass.

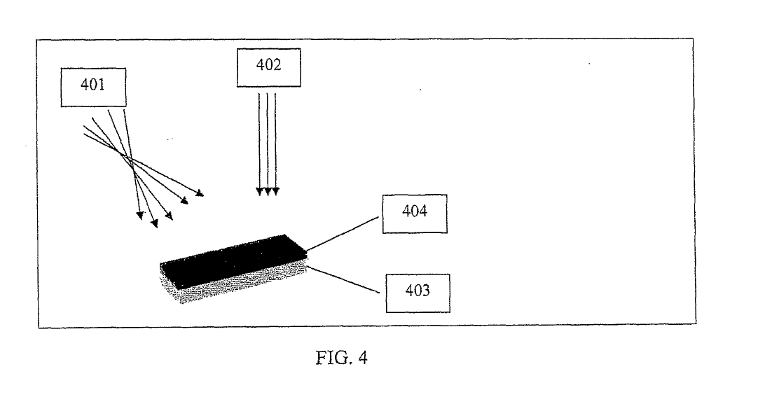

In some embodiments of the present invention, recording of a holographic image in a holographic recording media and curing occurs simultaneously. This is shown in FIG. 4. A holographic recording material (e.g., linear or crosslinked polymer film with covalently attached photo-dimerizable groups) (Item 404) on a substrate (Item 403) is exposed to an un-collimated light source for curing provided, for example, by a UV lamp (Item 401) and laser light (encoding a holographic image) provided by a laser (Item 402).

The methods for manufacturing holographic recording media and holographic sensors, and methods for recording holographic images according to an embodiment of the present invention can be used in mass-production processes. Examples of mass-production processes that are contemplated in the present invention include a web-based approach, where the medium is coated on a roll of flexible plastic film, and a substrate-based technique, where the coating is formed on a sheet of a rigid substrate, such as glass or on plastic held under tension. The substrate technique may involve manual or robotic manipulation of individual substrates though the various steps of the manufacturing process, and is suitable for small volume applications. The web-based approach is more suited for higher volume applications, but may equally be used on a small scale for small volumes.

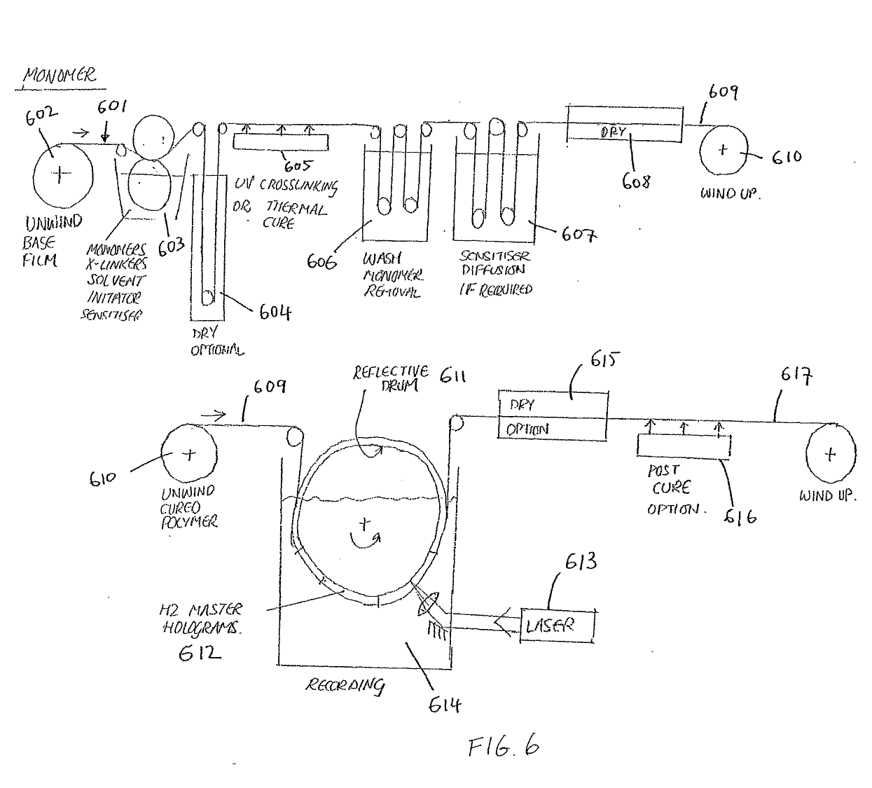

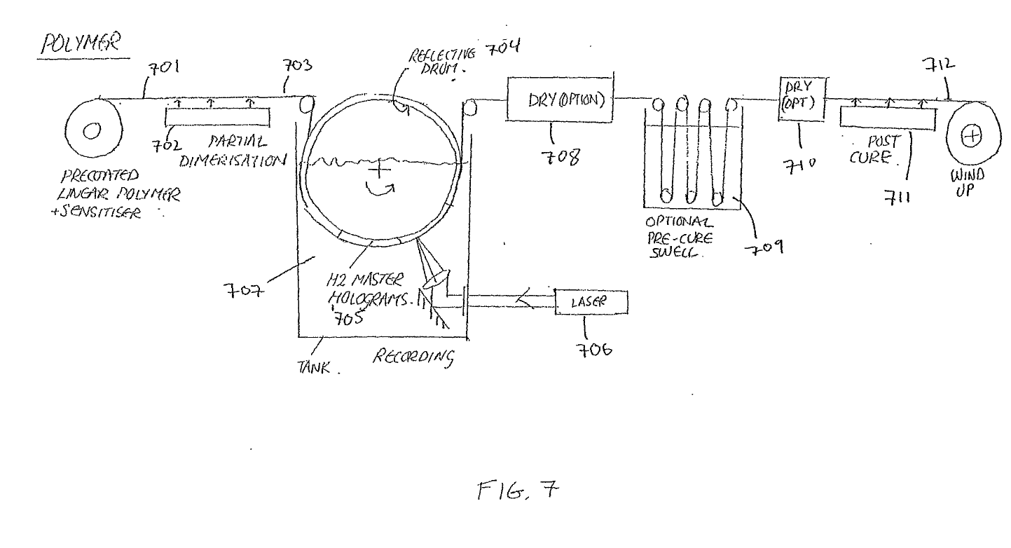

Web-based processes according to embodiments of the present invention include the ones schematically represented in FIGS. 6 and 7. Web-based processes are described, but the equivalent steps in the substrate approach will be readily envisioned.

Base film (PET to TAC), optionally with a priming layer may be coated using conventional roll or blade coating techniques. FIG. 6 is a schematic representation of a suitable monomer coating route according to an embodiment of the present invention. A base film (Item 601) is unwound from a base film roll (Item 602) and contacted with a mixture (Item 603) of monomers, crosslinkers, initiator, and optionally in a suitable solvent to obtain the correct viscosity for coating, if required. The coating solution should contain a sensitizer at this stage to match the laser wavelength for recording the hologram, and if the crosslinking step is to be thermally initiated. The crosslinking may also be UV initiated in which case the sensitiser should be added in a diffusion step after the UV crosslinking. Following coating, optionally, any solvent is dried off in a drying environment (Item 604; e.g., a drying chamber) to leave the monomer based coating, which is then either thermally linked or crosslinked by exposure to a flood DV lamp (Item 605) to form the matrix. Residual monomer and other low molecular weight components may then be removed by washing in a wash medium (Item 606).

Following drying, the resulting coated film is dry and non-tacky and may be rewound and kept ready for hologram recording. Alternatively, at this stage, sensitizer may be diffused into the coating before the drying stage by contacting with a sensitizer medium (Item 607). Alternatively, the sensitizer diffusion may be added immediately prior to recording. Cured polymer film, with or without sensitizer (Item 609), is wound on a polymer roll (Item 610). During the recording, the film (Item 609) is wrapped around a reflective drum (Item 611) on which are precision-placed master holograms (Items 612) of the image to be recorded. Typically, these are so called H2 holograms, which are replicates of an original H1 master of the original image. A laser (Item 613) of appropriate wavelength is used to form a focused linear stripe of energy along the length of the drum. This writes the holographic sensor into the photopolymer medium as the drum rotates. The recording can be done either dry, or, if the recorded wavelength is to be shorter than the laser wavelength, the recording may be done in a tank of suitable swelling liquid (Item 614), typically buffer solution. Drying in a drying environment (Item 615) is typically necessary immediately after the recording if the hologram is written wet. A post cure step to dimerize unreacted groups may be performed at this stage. This may be carried out by flood exposure to a UV lamp (Item 616). The film containing holographic sensors (Item 617) may then be rewound and sent for conversion into individual hologram sensors using well known manufacturing methods.

FIG. 7 is a schematic representation of a suitable polymer coating route according to an embodiment of the present invention. Linear polymer comprising dimerizable groups and optionally receptors, and further optionally sensitizer, may be coated on base film using the same methods as described for the monomer process. Such film is dry and may be rewound and stored (not shown). The pre-coated linear polymer (Item 701) is crosslinked through partial dimerization by flood exposure to a UV lamp (Item 702). During recording, the film (Item 703) may be wrapped around a reflective drum (Item 704) on which are precision placed master holograms (Items 705) of the image to be recorded. Typically, these are so called H2 holograms which are replicates of an original H1 master of the original image. A laser (Item 706) of appropriate wavelength is used to form a focused linear stripe of energy along the length of the drum. This writes the holographic sensor into the photopolymer medium as the drum rotates. The recording can be done either dry, or, if the recorded wavelength is to be shorter than the laser wavelength, the recording may be done in a tank of suitable swelling liquid (Item 707), typically buffer solution. The recording process is the same as for the monomer process. After drying in a drying environment (Item 708), an optional pre-cure swell in a suitable swelling liquid (Item 709) may be used to control the replay wavelength of the sensor as described herein. An optional drying stage in a drying environment (Item 710) may be necessary to control the extent of swelling. A post cure step to dimerize unreacted groups may be performed at this stage. This is carried out by flood exposure to a UV lamp (Item 711). The film containing holographic sensors (Item 712) may then be rewound and sent for conversion into individual hologram sensors using well known manufacturing methods.

If two holograms are to be recorded in the same medium, the processes may be interrupted after the recording and optional drying steps and the film wound up. H2 holograms of the second image are then placed on the drum, and the film passed though the recording and optional drying step a second time. The process may be repeated if it is possible to record more holograms in the medium, subject to sufficient availability of unreacted dimerizable groups.

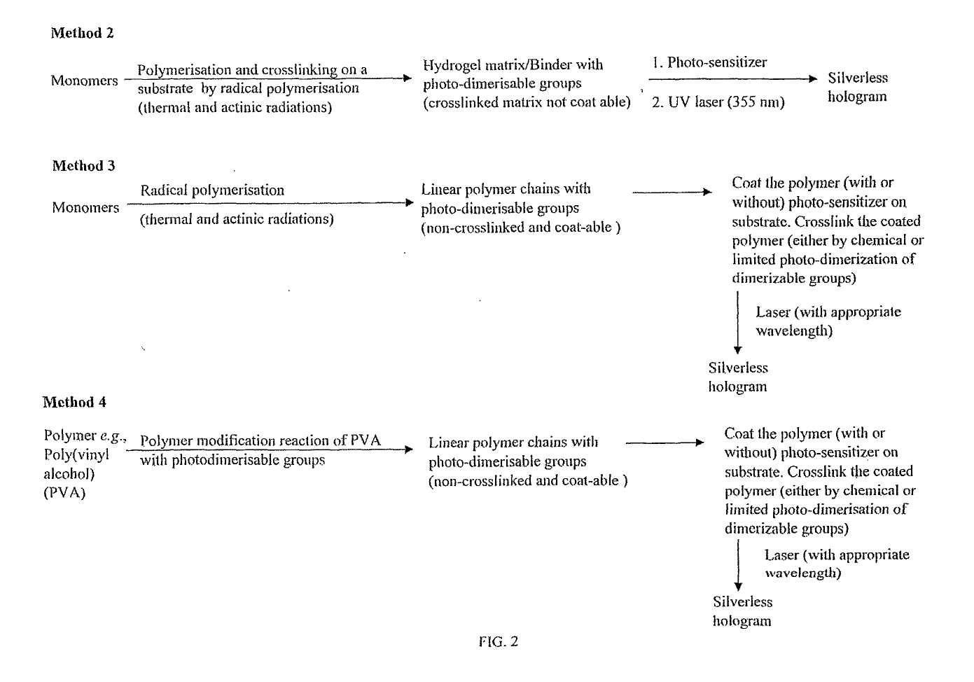

Further exemplary processes for manufacturing a volume hologram or holographic sensor comprising the holographic recording media described herein are shown in Methods 2-4 of FIG. 2.

### EXEMPLIFICATION

### Preparative Example

### Synthesis of pH-Responsive Hologram Sensor

### Synthesis of 1-(2-hydroxy-ethyl)-3,4-dimethyl-pyrrole-2,5-dione (1)

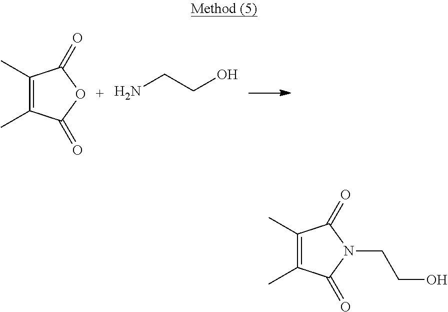

Procedure: 4.526 ml (75 mmol) of 2-aminoethanol was added to a stirred solution of 3.1527 g (25 mmol) dimethylmaleic anhydride in 125 ml toluene. The mixture was boiled at 130-150° C. for 5 h using a reflux condenser with a water trap to remove water as the side product. The reaction mixture was cooled at room temperature and the solvent was evaporated under reduced pressure at 40° C. The product was purified by column chromatography by using 1:1 ratio of n-hexane and ethylacetate and characterized by ¹H-NMR. Yield: 83% Physical state: colorless crystals. ¹H NMR (CDCl₃): δ (ppm)=1.94 (s, 6H, 2 CH₃), 2.43 (s, 1H, O—H), 3.65 (t, 2H, N—CH₂), 3.71 (t, 2H, O—CH₂).

### Synthesis of 2-(3,4-dimethyl-2,5-dioxo-2,5-dihydro-1H-pyrrol-1-yl)ethyl methacrylate (2)

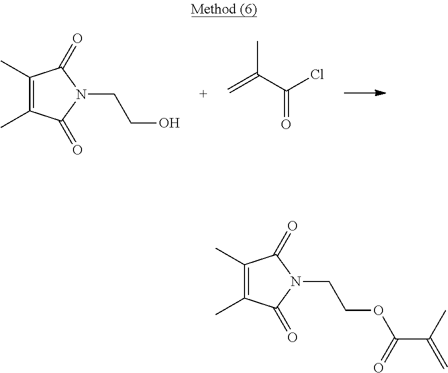

Procedure: 0.64 g (3.8 mmol) of 1-(2-hydroxy-ethyl)-3,4-dimethyl-pyrrole-2,5-dione (1) and 0.5762 ml (4.2 mmol) of triethylamine were added to 11 ml dichloromethane. The mixture was cooled to 0° C. in an ice bath. 0.4065 ml (4.2 mmol) of meth-acryloyl chloride was added drop wise to the stirred suspension. The suspension was stirred at 4° C. initially for 1 h and was then allowed to stir at room temperature for 24 h. The solvent was evaporated under reduced pressure at 40° C. The product was characterized by H-NMR. Yield: 98%. Physical state: colorless viscous liquid. ¹H NMR (CDCl₃): δ (ppm)=1.86 (s, 3H, CH₃), 1.93 (s, 6H, 2CH₃) 3.77 (t, 2H, N—CH₂), 4.22 (t, 2H, O—CH₂), 5.52 (1H, ═CH₂), 6.03 (1H, ═CH).

### Example 1

### Synthesis of Hydrogel Sensor

2-hydroxyethylmethacrylate (HEMA, 0.25 g, 1.92*10⁻³ mol), ethylene glycol dimethacrylate (EDMA, 13.8 mg, 6.9*10⁻⁵ mol; i.e., a crosslinker), methacrylic acid (MAA, 11.9 mg, 1.4*10⁻⁴ mol) and 2-(3,4,-dimethyl-2,5-dioxo-2,5-dihydro-1H-pyrrol-1-yl)ethyl methacrylate (DMIMA, 43.9 mg, 1.8*10⁻⁴ mol) were dissolved in 319 μl of 4 wt % 2-dimethoxy-2-phenyl acetophenone (DMPA) in DMSO. Solution was poured on the polyester side of an aluminized polyester sheet. A glass slide modified with methacryloxypropyltriethoxysilane was gently lowered onto the poured solution. The slides were exposed to UV lamp (˜350 nm) for 1 h. The UV initiated free radial polymerization and crosslinking resulted in formation of a substrate attached thin hydrogel sensor film. The glass slides with hydrogel sensor film were dipped in deionized (DI) water for 30 minutes, peeled off from the polyester/Al sheet, washed with DI water, dried under nitrogen flow for 1-2 minutes and vacuum dried overnight at ambient temperature.

### Example 2

### Synthesis of pH-Responsive Sensor

The glass slides with hydrogel sensor films prepared in Example 1 were immersed in 0.4 wt % thioxanthone solution (prepared in DMSO) for 10 minutes, dried under nitrogen flow for 1-2 minutes and vacuum dried overnight at 40° C. The hydrogel sensor film was placed on a front surface mirror at a rough angle of 3° in relation to the surface of the mirror. The hydrogel sensor film was exposed for 5 seconds using a Nd:YAG laser coupled with a Third Harmonic Generator (355 nm, 165 ml). This results in the dimerization of the maleimide groups of DMIMA and formation of fringes. Thus the fringes here consist of a photo-chemically generated product from the dimerization of the DMI groups. The holographic fringes were recorded in the dry state and are spaced λ/2 nm, where λ is the wavelength of the laser used to irradiate the hydrogel sensor film. In the present case the fringes are spaced 177 nm apart. The hydrogel sensor film now has two categories of crosslinking: random crosslinking from EDMA, and well-ordered DMIMA crosslinks spaced 177 nm apart in dry state (due to the dimerization of DMI groups).

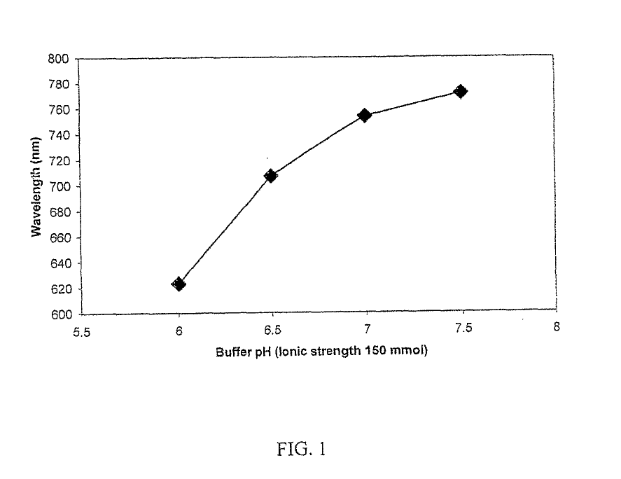

The hydrogel sensor films were immersed in various buffer solutions at pH 6 to 7.5 (ionic strength 150 mmol). The results are illustrated in the FIG. 1., which shows a change of the replay wavelength of the recorded hologram towards longer wavelength with higher pH (The polymer matrix of the sensor in FIG. 1 was obtained from HEMA/MAA/DMIMA/EDMA (83/6/8/3 mol %), Polymer B2 in Table 2).

The hydrogel sensor film showed a replay wavelength around 623 nm in 150 mM MES buffer solution of pH 6.0. A replay wavelength in the visible red spectrum also gave an estimate of the volume degree of swelling of the hydrogel sensor film and the value was assumed to be 1.75. In addition, the hydrogel sensor film showed a reply wavelength of 707 nm in 150 mM MES buffer solution of pH 6.5 and the volume degree of swelling was assumed to be 2.0. A further increase in the pH of buffer solution increased the replay wavelength of the hologram (see FIG. 1). The replay wavelength at the tested pHs are shown in Table 1. At higher pH values, hydrophilicity of the sensor hologram increased which in turn increased the volume degree of swelling of the hydrogel film. This eventually, results in a volume hologram sensor whose replay wavelength can be tuned as a function of pH.

TABLE 1

| pH | Replay Wavelength (nm) | Buffer type (150 mM) |
|---|---|---|
| 6 | 623 | MES |
| 6.5 | 707 | MES |
| 7 | 754 | MOPS |
| 7.5 | 772 | MOPS |

The sensor response time can be adjusted according to needs by changing various polymer parameters. For example, the polymer can be altered by decreasing the mol % of photo-dimerisable compound, mol % of EDMA, mol % of MAA and by incorporating hydrophilic or hydrophobic monomers. In addition, by varying the exposure time on the UV laser, the reply wavelength and response time can be altered.

Similarly, various stimuli responsive volume hologram sensors can be formulated. Suitable stimuli are described in previous sections.

### Example 3

### Additional Holographic Sensors

Table 2 shows the compositions of nine polymer matrices. These polymer matrices were used to prepare holographic sensors analogously to the above exemplified procedures. The holographic sensors respond to pH (buffered solutions) or water (acetone/water mixtures).

TABLE 2

| | | | | | Hologram has sensor |
|---|---|---|---|---|---|
| | | | | | activity |
| | HEMA | MAA | DMIMA | EDMA | (in acetone/water mixture |
| Polymer | (mol %) | (mol %) | (mol %) | (mol %) | or in buffer solutions) |
| A1 | 88 | 6 | 4 | 2 | yes |
| A2 | 84 | 6 | 8 | 2 | yes |
| A3 | 80 | 6 | 12 | 2 | yes |
| B1 | 87 | 6 | 4 | 3 | yes |
| B2 | 83 | 6 | 8 | 3 | yes |
| B3 | 79 | 6 | 12 | 3 | yes |
| C1 | 86 | 6 | 4 | 4 | yes |
| C2 | 82 | 6 | 8 | 4 | yes |
| C3 | 79 | 6 | 12 | 4 | yes |

### Example 4

### Glucose Responsive Holographic Sensors

3-APB as a glucose responsive ligand was synthesised according to the procedures described in Kabilan et al., Biosensors and Bioelectronics, 20 (2005) 1602. N-[2-(3,4-dimethyl-2,5-dioxo-2,5-dihydro-pyrrol-1-yl)-ethyl]-acrylamide (DMIAAm) was synthesized according to the procedures described in C. D. Vo et al., M. Colloid Polym. Sci. 2002, 280, 400. DMIAAm is an acrylamide based photo-dimerisable monomer, that is, a monomer comprising a dimerisable chemical group.

### Synthesis of Glucose Responsive Thin Hydrogel Film

Acrylamide (0.231 g, 3.25*10⁻³ mol), N,N-methylene-bis-acrylamide (19.5 mg, 1.266*10⁻⁴ mol), 3-APB (96.7 mg, 5.065*10⁻⁴ mol) and DMIAAm (92.2 mg, 3.376*10⁻⁴ mol) were dissolved in 972 μl of 2 wt % 2-dimethoxy-2-phenyl acetophenone (DMPA) in DMSO. Solution was poured on the polyester side of an aluminized polyester sheet. A glass slide modified with methacryloxypropyltriethoxysilane was gently lowered onto the poured solution. The slides were exposed to UV lamp (˜350 nm) for 30 min. The UV initiated free radial polymerization and crosslinking resulted in formation of a substrate attached thin hydrogel sensor film. The glass slides with hydrogel sensor film were dipped in deionized (DI) water for 1 h, peeled off from the polyester/Al sheet, washed with DI water to remove unreacted monomers, dried under nitrogen flow for 1-2 minutes and vacuum dried overnight at ambient temperature.

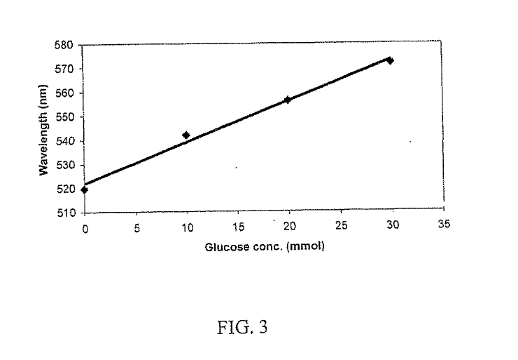

The glass slides with hydrogel sensor films were immersed in 0.4 wt % thioxanthone solution (prepared in DMSO) for 10 minutes, dried under nitrogen flow for 1-2 minutes and vacuum dried overnight at 40° C. The hydrogel sensor film was placed on a front surface mirror at a rough angle of 3° in relation to the surface of the mirror. The distance between the lens and sample was 20.7 cm. The hydrogel sensor film was exposed for 2 seconds using a Nd:YAG laser coupled with a Third Harmonic Generator (355 nm, 165 mJ). This results in the dimerisation of the maleimide groups of DMIMA and formation of fringes. The replay wavelength of glucose responsive hologram was measured in 0-30 mM glucose solution. Various concentration of glucose solutions were prepared in phosphate buffer, pH=7.4 (˜25 mM ionic strength). The results are summarized FIG. 3 and Table 3.

TABLE 3

| Glucose solutions prepared in 25 mmol | Replay wavelength of glucose |
|---|---|
| phosphate buffer (pH = 7.4) | responsive hologram (nm) |
| 0 | 519.7 |
| 10 | 541.9 |
| 20 | 556.1 |
| 30 | 572.0 |

It is believed that 3-APB (in hydrogel sensor hologram) interacts with glucose and results in the formation of a negatively charged boronate species, and that this in turn increases the volume degree of swelling and the replay wavelength of hologram increases as a function of glucose concentration.

Crosslinking in the hydrogel film can be tuned to achieve a desired wavelength change upon interaction with a given glucose concentration. If a larger change in the replay wavelength is required, the crosslinking density in the hydrogel film can be reduced and vice a versa. Also, the laser exposure duration and extent of dimerisation in fringe areas will influence the replay wavelength of the hologram at a given glucose concentration. To improve the properties of the hologram and its response to an analyte (e.g., glucose) the following parameters can be varied: crosslinking density, extent of dimerisation, laser exposure duration, additional co-monomer to improve the % R and response time, buffer type and its ionic strength.

Additional Glucose Responsive Holographic Sensors

Holograms with similar formulation as described in above example were formulated. The laser exposure parameters were varied and replay wavelength was monitored. The results are shown in Table 4.

TABLE 4

| | | | Visually |
|---|---|---|---|
| | | | perceptible replay |
| | | | wavelength in 50 |
| | | Visually | mM glucose |
| | Distance between | perceptible replay | (prepared in ~150 |
| Laser exposure | the lens and | wavelength in | mmol phosphate |
| duration (sec) | sample (cm) | phosphate buffer | buffer) |
| 5 | 20.7 | No visible | Red region of |
| | | hologram | spectrum |
| 10 | 30 | No visible | Red region of |
| | | hologram | spectrum |

### Example 5

### Synthesis of pH-Responsive Sensor by Simultaneous Curing and Writing a Hologram

A hydrogel sensor is synthesized as described above in Example 1. The glass slides with hydrogel sensor films are then immersed in 0.4 wt % thioxanthone solution (prepared in DMSO) for 10 minutes, dried under nitrogen flow for 1-2 minutes and vacuum dried overnight at 40° C. The hydrogel sensor film are placed on a front surface mirror at a rough angle of 3° in relation to the surface of the mirror. The hydrogel sensor film are simultaneously exposed to

1. Nd:YAG laser coupled with a Third Harmonic Generator (355 nm, 165 mJ). This results in the dimerisation of the maleimide groups of DMIMA and formation of fringes; and

2. UV lamp (˜350 nm). This results in curing by random dimerisation of the DMIMA.

This process is schematically shown in FIG. 4.

It is believed that because curing and hologram writing occurs simultaneously, varying the exposure to the UV lamp and laser can be used to formulate a hologram with desired percentage reflection and volume degree of swelling.

### Example 6

### Holographic Sensor Prepared by Post Curing of Residual (i.e., Unreacted) Dimerisable Groups

Hydrogel film (with 84 mol % HEMA, 6 mol % MAA, 8 mol % DMIMA and 2 mol % EDMA) prepared analogously to the procedures described in Example 1 The glass slides with hydrogel sensor films were immersed in 0.4 wt % thioxanthone solution (prepared in DMSO) for 10 minutes, dried under nitrogen flow for 1-2 minutes and vacuum dried overnight at 40° C. The hydrogel sensor film was placed on a coin at a rough angle of 0° in relation to the surface of the coin. The distance between the lens and sample was 19.5 cm. The hydrogel sensor film was exposed for 20 seconds using a Nd:YAG laser coupled with a Third Harmonic Generator (355 nm, 165 mJ). This results in formation of a hologram. Thioxanthone solution (0.4 wt % in DMSO) was carefully poured on the hologram and the assembly was kept for 10 mins followed by exposure to a UV lamp (˜350 nm) for 30 mins. This results in dimerisation of unreacted dimerisable groups that were predominantly present in the dark fringes. DMSO was removed by washing with acetone/water mixture. The hologram was immersed in 5 mM phosphate buffer (pH=6.5) for 1 h and a visible hologram in blue to green spectrum was seen. The hologram was washed with DI water and dried. This dried hologram has a fringe spacing which is different from the dry hologram described in Example 1.

The resulting hologram in dry state was however not colored but in approximate shades of grey. This may be because the matrix was additionally crosslinked in the swollen state leading to the formation of some fringes corresponding to reflection of wavelengths across the visible spectrum. Despite this the image was well resolved and showed clear detail.

The sensor was responsive to breath. When breathed on, the color of the image turned blue/green. This was interpreted as the swelling of the matrix (due to moisture in the breath) causing the fringes in the UV to shift more into the blue/green region.

### Example 7

### Fructose and pH Responsive Holographic Sensor Prepared by Incorporation of an Adduct in the Polymer Matrix

The adduct 3-(3,4-dimethyl-2,5-dioxo-2,5-dihydro-1H-pyrrol-1-yl)phenylboronic acid (3-DMI-PB) (see below) which comprises a photo-dimerisable group linked to a boronic acid was prepared by reacting 3-aminophenyl boronic acid with dimethyl maleic anhydride using appropriate solvent and heating the mixture between 130-150° C. for 3-5 h.

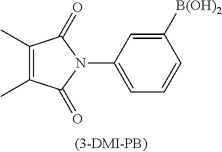

50 mg of 3-DMI-PB was dissolved in 1 ml of 18.8 mM thioxanthone solution (prepared in DMSO). 400 μl of above solution was carefully poured on a thin hydrogel film (composed of 84 mol % HEMA, 6 mol % MAA, 8 mol % DMIMA and 2 mol % EDMA). The assembly was kept for 20 min followed by exposure to a UV lamp (>300 nm) for 30 minutes. This caused the unreacted DMI groups in the non fringe areas of the photopolymer hologram to react with the 3-DMI-PB and resulted in formation of a cyclobutane ring (see below scheme) to form a functional dimeric structure covalently bonded to the hydrogel film.

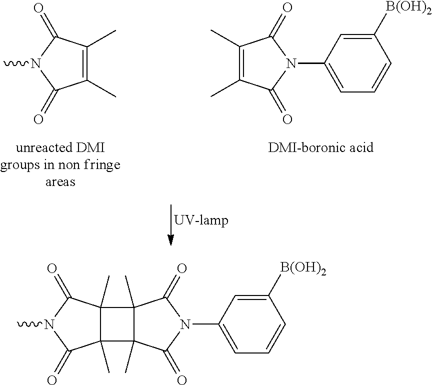

The resulting holographic sensor was then immersed overnight in deionised water. No visible color was seen in the hologram. This is due to the fact that the pH responsive holographic sensor contracts in DI water and the replay wavelength moves to the LTV region. The hologram was subsequently immersed in various concentrations of fructose solutions and the results are summarized in Table 5.

TABLE 5

| Solvent | Immersion Duration | | Observation |
|---|---|---|---|
| DI water | >12 | h | no visible color |
| 5 mM Fructose (in DI | 3 | h | no visible color |
| water) | | | |
| 15 mM Fructose (in DI | 2 | h | no visible color |
| water) | | | |
| 250 mM Fructose (in DI | >12 | h | green color hologram |

water)

### Example 8

### Recording of Two Visible Holograms Using Post Swelling

Thin hydrogel films were synthesized using 83 mol % HEMA, 6 mol MAA, 8 mol % DMIMA and 3 mol % EDMA. The dry hydrogel film was exposed to 355 nm laser for 5 sec using a coin as shim. The resulting hologram was immersed in DI water. The wet hologram was exposed again to the 355 nm laser for 5 sec using a different coin as a shim. The replay wavelength of two holograms was monitored in different buffer solutions. The results are summarized in Table 6 (MOPS stands for 3-(N-Morpholino)-propanesulfonic acid).

TABLE 6

| Buffer (pH) | Buffer type | Result | |
|---|---|---|---|
| | | Image 1 (5 p coin) | Image 2 |
| | | | (10 p coin) |
| 7.0 | 14 mM MOPS | Red | Green |
| 7.4 | 13 mM MOPS | No visible image | Red |
| 5.9 | Phosphate buffer | No visible image | No visible |
| | | | image |

In addition, two images appeared in sequence, when the hologram was immersed in the pH 7.0 phosphate buffer. During the initial swelling stage, the image 1 was visible. At high swelling stage (before the equilibrium), the image 1 disappeared in infra red region and the image 2 appeared in the visible spectrum.

While this invention has been particularly shown and described with references to example embodiments thereof, it will be understood by those skilled in the art that various changes in form and details may be made therein without departing from the scope of the invention encompassed by the appended claims.

What is claimed is:

1. A holographic sensor, comprising:
(a) a holographic recording media comprising a polymer matrix; and
(b) at least one holographic image recorded in said holographic recording media as diffraction fringes, wherein the diffraction fringes comprise a dimeric structure that includes a cyclic bridge; and
wherein said holographic recording media responds to an external stimulus by providing at least one output signal.

2.-3. (canceled)

4. The holographic sensor of claim 1, wherein the dimeric structure crosslinks the polymer matrix.

5. The holographic sensor of claim 1, wherein the polymer matrix is in addition to crosslinking through dimeric structures that are part of the diffraction fringes further randomly crosslinked through crosslinking groups different from the dimeric structure.

6.-14. (canceled)

15. The holographic sensor of claim 1, wherein the diffraction fringes comprise (i) dark fringes with relatively low density of dimeric structures, and (ii) bright fringes associated with relatively high density of dimeric structures, and the polymer matrix responds to an external stimulus with a higher degree of swelling in the dark fringes than in the bright fringes, leading to a variation in reproduction wavelength of the holographic image recorded in the holographic recording media.

16.-18. (canceled)

19. The holographic sensor of claim 1, wherein the polymer matrix comprises gelatin, or a polymer of one or more of 2-hydroxyethylmethacrylate (HEMA), 2-hydroxypropylmethacrylate (HPMA), N,N-dimethylacrylamide (DMAA), poly(ethylene glycol) mono-methacrylate (PEGMA), vinyl acetate, acrylamide, N-isopropylacrylamide, acrylic acid (AA), methacrylic acid (MAA), N,N-methylenebisacrylamide (BIS), ethyleneglycol dimethacrylate (EDMA), 2-acrylamido-2-methylpropane sulfonic acid (AMPS), sodium salt of methacrylic acid, 2-(dimethylaminoethyl)methacrylate (DMAEMA), Styrene 4-sulfonic acid, and 2-(N,N Dimethyl-N-(2-methacryloxyethyl)ammonium)ethanoic acid.

20. The holographic sensor of claim 19, wherein the cyclic bridge is a cyclobutyl.

21. The holographic sensor of claim 20, wherein the diffraction fringes comprise a dimer of one or more of cinnamoyl, chalcone, anthracene, coumarin, stilbazolium, maleimide, or a derivatives thereof.

22. The holographic sensor of claim 21, wherein the interference fringes comprise a dimer represented by the formula: 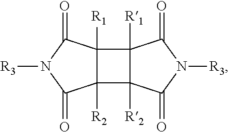
wherein:
R₁, R₂, R′₁, and R′₂ are each independently a C1-C10 alkyl, C1-C10 alkoxy, C3-C10 cycloalkyl, C6-C18 aryl, C6-C18 aryloxy, each optionally substituted with —OH, —NR^{b}R^{c}, or a halogen or R₁ and R₂, taken together with the carbon atoms to which they are attached form a saturated or unsaturated five or six-member hydrocarbon or heterocyclic ring, wherein the C1-C10 alkyl, C1-C10 alkoxy, C3-C10 cycloalkyl, C6-C18 aryl, C6-C18 aryloxy and a hydrocarbon or heterocyclic ring are each optionally substituted with —OH, —NR^{b}R^{c}, or a halogen;
R₃ is a linear or branched C1-C20 alkyl or a C3-C10 cyclic alkyl having one or more carbon atoms optionally replaced by nitrogen or oxygen and/or optionally substituted with —COOH, —COX, —OH, —NR^{b}R^{c}, acrylate, methacrylate, acrylamide, —SR^{a}, —Si(R^{a})₂X, or Si(R^{a})₃; or R₃ is a poly(ethylene glycol) (PEG) with average molecular weight of ≦12000, wherein the hydroxyl group is optionally replaced by amines, —COOH, —COX, acrylate, methacrylate, acrylamide, —SR^{a}, —Si(R^{a})₂X or —Si(R^{a})₃; or R₃ is —(PEG)_{mol wt≦12000}C(O)O—NHS, or —(PEG)_{mol wt≦12000}C(O)O-sulfo-NHS;
X is a halogen;
R^{a} is a hydrogen or a linear or branched C1-C10 alkyl or a C3-C10 cyclic alkyl; and
R^{b} and R^{c} are each independently a hydrogen or a C1-C6 alkyl.

23. The holographic sensor of claim 1, wherein the dimerisable chemical groups are covalently bonded to the polymer matrix and the polymer matrix comprises a polymer of first compounds comprising the dimerisable chemical groups, and second compounds selected from the group consisting of 2-hydroxyethylmethacrylate (HEMA), 2-hydroxypropylmethacrylate (HPMA), N,N-dimethylacrylamide (DMAA), poly(ethylene glycol) mono-methacrylate (PEGMA), vinyl acetate, acrylamide, N-isopropylacrylamide, acrylic acid (AA), methacrylic acid (MAA), N,N-methylenebisacrylamide (BIS), ethyleneglycol dimethacrylate (EDMA), 2-acrylamido-2-methylpropane sulfonic acid (AMPS), sodium salt of methacrylic acid, 2-(dimethylaminoethyl)methacrylate (DMAEMA), Styrene 4-sulfonic acid, and 2-(N,N Dimethyl-N-(2-methacryloxyethyl)ammonium)ethanoic acid.

24.-25. (canceled)

26. The holographic sensor of claim 23, wherein the diffraction fringes comprise a dimeric structure represented by the formula: 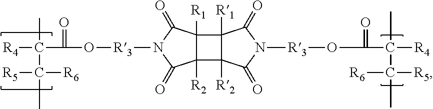
wherein
R₁, R₂, R′₁, and R′₂ are each independently a C1-C10 alkyl, C1-C10 alkoxy, C3-C10 cycloalkyl, C6-C1-8 aryl, C6-C1-8 aryloxy, each optionally substituted with —OH, —NR^{b}R^{c}, or a halogen or R₁ and R₂, taken together with the carbon atoms to which they are attached form a saturated or unsaturated five or six-member hydrocarbon or heterocyclic ring, wherein the C1-C10 alkyl, C1-C10 alkoxy, C3-C10 cycloalkyl, C6-C18 aryl, C6-C18 aryloxy and a hydrocarbon or heterocyclic ring are each optionally substituted with —OH, —NR^{b}R^{c}, or a halogen;
R′₃ is a linear or branched C1-C20 dialkyl or C3-C10 cyclic dialkyl, wherein the C1-C10 dialkyl or C3-C10 cyclic dialkyl has one or more (e.g., 1, 2, 3, 4, 5, 6, 7, 8, 9, or 10) carbon atoms are optionally replaced by nitrogen or oxygen, or R′3 is —C(O)—, —Si(R^{a})₂—, or —(PEG)_{mol wt≦12000}-;
R₄, R₅ and R₆ are each independently a hydrogen or a C1-C10 alkyl, C1-C10 alkoxy, C3-C10 cycloalkyl, C6-C18 aryl, C6-C18 aryloxy, each optionally substituted with —OH, —NR^{b}R^{c}, or a halogen;
R^{a} is a hydrogen or a linear or branched C1-C10 alkyl or a C3-C10 cyclic alkyl; and
R^{b} and R^{c} are each independently a hydrogen or a C1-C6 alkyl.

27.-28. (canceled)

29. The holographic sensor of claim 26, wherein the diffraction fringes comprise a dimer represented by the formula:

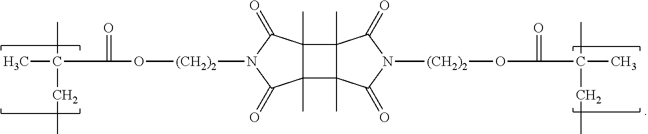

30.-34. (canceled)

35. The holographic sensor of claim 1, further comprising a plurality of functional dimeric structures that include a cyclic bridge formed by dimerization via photocycloaddition of a first dimerisable chemical group covalently attached to the polymer matrix and an adduct of formula D-FG, wherein D is a second dimerisable chemical group and FG is a functionality conferring group.

36.-41. (canceled)

42. The holographic sensor of claim 35, wherein the functional dimeric structures are represented by structural formula (VIII): 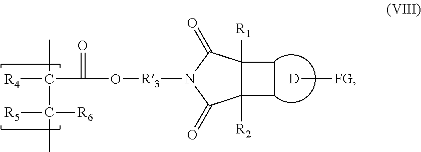
wherein
R₁ and R₂ are each independently a C1-C10 alkyl, C1-C10 alkoxy, C3-C10 cycloalkyl, C6-C18 aryl, C6-C18 aryloxy, each optionally substituted with —OH, —NR^{b}R^{c}, or a halogen or R₁ and R₂, taken together with the carbon atoms to which they are attached form a saturated or unsaturated five or six-member hydrocarbon or heterocyclic ring, wherein the C1-C10 alkyl, C1-C10 alkoxy, C3-C10 cycloalkyl, C6-C18 aryl, C6-C18 aryloxy and a hydrocarbon or heterocyclic ring are each optionally substituted with —OH, —NR^{b}R^{c}, or a halogen;
R′₃ is a linear or branched C1-C20 dialkyl or C3-C10 cyclic dialkyl, wherein the C1-C10 dialkyl or C3-C10 cyclic dialkyl has one or more (e.g., 1, 2, 3, 4, 5, 6, 7, 8, 9, or 10) carbon atoms are optionally replaced by nitrogen or oxygen, or R′3 is —C(O)—, —Si(R^{a})₂—, or —(PEG)_{mol wt≦12000}-;
R₄, R₅ and R₆ are each independently a hydrogen or a C1-C10 alkyl, C1-C10 alkoxy, C3-C10 cycloalkyl, C6-C18 aryl, C6-C18 aryloxy, each optionally substituted with —OH, —NR^{b}R^{c}, or a halogen;
R^{a} is a hydrogen or a linear or branched C1-C10 alkyl or a C3-C10 cyclic alkyl; and
R^{b} and R^{c} are each independently a hydrogen or a C1-C6 alkyl.

43. The holographic sensor of claim 42, wherein the functional dimeric structures are represented by structural formula (VIIb): 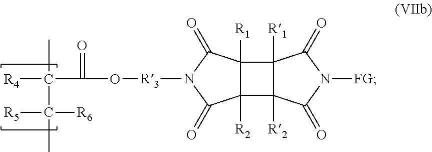
wherein
R₁, R₂, R′₁, and R′₂ are each independently a C1-C10 alkyl, C1-C10 alkoxy, C3-C cycloalkyl, C6-C1-8 aryl, C6-C1-8 aryloxy, each optionally substituted with —OH, —NR^{b}R^{c}, or a halogen or R₁ and R₂, taken together with the carbon atoms to which they are attached form a saturated or unsaturated five or six-member hydrocarbon or heterocyclic ring, wherein the C1-C10 alkyl, C1-C10 alkoxy, C3-C10 cycloalkyl, C6-C18 aryl, C6-C18 aryloxy and a hydrocarbon or heterocyclic ring are each optionally substituted with —OH, —NR^{b}R^{c}, or a halogen;
R′₃ is a linear or branched C1-C20 dialkyl or C3-C10 cyclic dialkyl, wherein the C1-C10 dialkyl or C3-C10 cyclic dialkyl has one or more (e.g., 1, 2, 3, 4, 5, 6, 7, 8, 9, or 10) carbon atoms are optionally replaced by nitrogen or oxygen, or R′3 is —C(O)—, —Si(R^{a})₂—, or —(PEG)_{mot wt≦}12000-;
R₄, R₅ and R₆ are each independently a hydrogen or a C1-C10 alkyl, C1-C10 alkoxy, C3-C10 cycloalkyl, C6-C18 aryl, C6-C18 aryloxy, each optionally substituted with —OH, —NR^{b}R^{c}, or a halogen;
R^{a} is a hydrogen or a linear or branched C1-C10 alkyl or a C3-C10 cyclic alkyl; and
R^{b} and R^{c} are each independently a hydrogen or a C1-C6 alkyl.

44. The holographic sensor of claim 43, wherein:
R₁ and R₂ are each independently a hydrogen, a halogen, a C1-C6 alkyl, or a C3-C6 cycloalkyl, each optionally substituted with —OH, —NR^{b}R^{c}, or a halogen;
R′₃ is a linear or branched C1-C6 dialkyl or C3-C6 cyclic dialkyl or poly(ethylene glycol) with average molecular weight of ≦12000; and
R₄, R₅ and R₆ are each independently a hydrogen or a C1-C6 alkyl.

45. The holographic sensor of claim 43, wherein:
R₁ and R₂ are each independently a C1-C6 alkyl, optionally substituted with —OH, —NR^{b}R^{c}, or a halogen; and
R′₃ is a linear or branched C1-C10 dialkyl or —(PEG)_{mol wt≦12000}-.

46. The holographic sensor of claim 45, wherein the functional dimeric structures are represented by structural formula (VIIc):

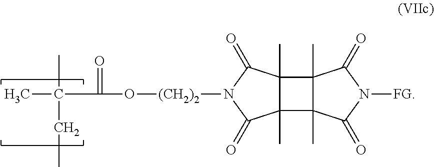

47. The holographic sensor of claim 46, wherein FG is a ligand, antibody, enzyme, protein, chelator, receptor, stimulus responsive oligomer or stimulus responsive polymer.

48. The holographic sensor of claim 46, wherein FG is a phenyl boronic acid or bis boronic acid.

49. The holographic sensor of claim 43, wherein FG is represented by structural formula (IXa) or (IXb): 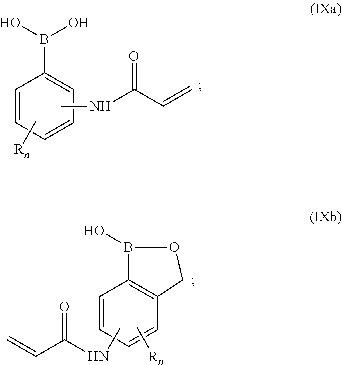
wherein n is 0, 1 or 2, and each R is independently hydrogen, halogen, C1-C6 alkyl, NO₂, cyano, COOalkyl, COalkyl or CF₃.

50. The holographic sensor of claim 49, wherein FG is represented by structural formula:

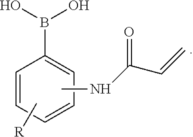

51. The holographic sensor of claim 1, further comprising a plurality of functional dimeric structures that include a cyclic bridge formed by dimerization via photocycloaddition of a first dimerisable chemical group covalently attached to the polymer matrix and an adduct of formula D-FG, wherein D is a second dimerisable chemical group and FG is a functionality conferring group, wherein the functional dimeric structure comprises a substructure represented by structural formula (X):

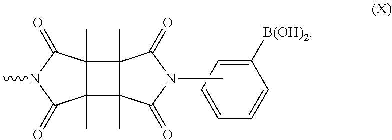

52. The holographic sensor of claim 1, wherein the holographic recording media further comprises a plurality of receptor groups covalently bonded to the polymer matrix.

53. The holographic sensor of claim 52, wherein the polymer matrix comprises a polymer prepared by copolymerization of monomers comprising the receptor groups, monomers comprising dimerisable chemical groups and one or more compounds selected from the group consisting of 2-hydroxyethylmethacrylate (HEMA), 2-hydroxypropylmethacrylate (HPMA), N,N-dimethylacrylamide (DMAA), poly(ethylene glycol) mono-methacrylate (PEGMA), vinyl acetate, acrylamide, N-isopropylacrylamide, acrylic acid (AA), methacrylic acid (MAA), N,N-methylenebisacrylamide (BIS), ethyleneglycol dimethacrylate (EDMA), 2-acrylamido-2-methylpropane sulfonic acid (AMPS), sodium salt of methacrylic acid, 2-(dimethylaminoethyl)methacrylate (DMAEMA), Styrene 4-sulfonic acid, and 2-(N,N Dimethyl-N-(2-methacryloxyethyl)ammonium)ethanoic acid.

54. The holographic sensor of 53, wherein the receptor groups are 3-acrylamidophenylboronic acid.

55. A holographic recording media, comprising:
(a) a polymer matrix; and
(b) a plurality of dimerisable chemical groups; wherein
(i) the dimerisable chemical groups dimerize by forming a cyclic bridge through photocycloaddition; and
(ii) the dimerisable chemical groups are distributed throughout the polymer matrix in a density sufficient to allow (1) recording of a hologram by dimerization of part of the dimerisable chemical groups and (2) detection of a change of the optical properties of the hologram upon response of the polymer matrix to the presence of an external stimulus.

56.-91. (canceled)

92. A method for recording a holographic image, the method comprising:
controlling (i) the fraction of dimerization of dimerisable chemical groups that form dimeric structures by photocycloaddition and (ii) retention of spatial positions of the dimeric structures, relative to each other and to dimerisable chemical groups that did not dimerize, to record the holographic image and enable a controlled observable response of the recorded holographic image, in a later presence of an external stimulus.

93-94. (canceled)

95. A method of detecting the presence of an external stimulus, comprising:
(1) providing a holographic sensor including:
(a) a holographic recording media comprising a polymer matrix; and
(b) at least one holographic image recorded in said holographic recording media as diffraction fringes, wherein the diffraction fringes comprise a dimeric structure that includes a cyclic bridge; and
wherein said holographic recording media responds to an external stimulus by providing at least one output signal; and
(2) detecting the presence of the at least one output signal to detect the presence of the external stimulus.

96. The method of claim 95, wherein the external stimulus is a fluid comprising an analyte and wherein providing the holographic sensor comprises swelling the holographic recording media.

97. The method of claim 96, wherein the swelling of the holographic recording media depends on the concentration of the analyte in the fluid.

98.-159. (canceled)

160. The holographic sensor of claim 1, wherein the cyclic bridge is a cyclobutyl.

161. The holographic sensor of claim 1, wherein the diffraction fringes comprise a dimer of one or more of cinnamoyl, chalcone, anthracene, coumarin, stilbazolium, maleimide, or a derivatives thereof.
